(19) United States
(12) Patent Application Publication
(10) Pub. No.: US 2025/0092526 A1
(43) Pub. Date: Mar. 20, 2025

(54) SURFACE MODIFICATION METHOD, METHOD FOR PRODUCING RESIN PLATING MATERIAL, AND ELECTROLESS PLATING APPARATUS

(71) Applicant: Ushio Denki Kabushiki Kaisha, Tokyo (JP)

(72) Inventors: Taro ARIMOTO, Tokyo (JP); Masaki MIURA, Tokyo (JP); Fumitoshi TAKEMOTO, Tokyo (JP)

(73) Assignee: Ushio Denki Kabushiki Kaisha, Tokyo (JP)

(21) Appl. No.: 18/709,641

(22) PCT Filed: Mar. 16, 2022
(86) PCT No.: PCT/JP2022/011787

§ 371 Date: May 13, 2024

(30) Foreign Application Priority Data
Nov. 30, 2021 (JP) 2021-193849
Nov. 30, 2021 (JP) 2021-193863

(51) Int. Cl. C23C 18/20

(52) U.S. Cl. CPC C23C 18/204

(57) ABSTRACT

Provided is a surface modification method capable of imparting adhesion to the surface of a base material in a more controllable manner than before without substantially providing irregularities on the surface of the base material. The surface modification method includes: a step (a) of preparing a base material containing an insulating resin material; and a step (b) of irradiating the surface of the base material with ultraviolet light having a wavelength of 200 nm or less, in an atmosphere with an oxygen concentration of 0.01 vol % to 10 vol %, to modify a treatment target region including the surface of the base material, into a microporous layer including voids of nanometer (nm) order size.

### TECHNICAL FIELD

The present invention relates to a method for modifying a surface state of a base material and particularly relates to a surface modification method using light. The present invention also relates to a method for producing a resin plating material in which plating is formed on a base material containing a resin material. The present invention also relates to an electroless plating apparatus suitable for producing such a resin plating material.

### BACKGROUND ART

A wiring board with a wiring pattern provided on a surface of an insulating resin material is known. This wiring board is conventionally obtained by providing an electroless plating layer, called a seed layer, on a resin serving as a base material and providing an electrolytic copper plating layer on the electroless plating layer. Another known method is to create a wiring board in which copper foil is bonded and joined to one or both sides of an insulating resin material using an adhesive.

To obtain stable electrical characteristics, the resin and the seed layer need to be firmly adhered to each other. To enhance adhesion, a conventionally known method is to roughen the surface of a resin to provide irregularities, followed by the formation of a seed layer on the resin surface where the irregularities are formed. The resin and the seed layer are firmly fixed by the anchor effect derived from the presence of irregularities.

Meanwhile, in a system called 5G communication, which has been developed in recent years, an electric signal with an extremely high frequency is used. Such a high-frequency current is unlikely to flow in the center of a conductor due to a phenomenon called the skin effect and flows only in the surface layer portion of the conductor. When the surface of the conductor has irregularities, a signal transmission path is lengthened, resulting in increased transmission loss. Therefore, especially a wiring board scheduled to handle a high-frequency signal is required to have as few irregularities as possible on the surface of the conductor.

The following Patent Document 1 describes that a resin material is finely roughened with ultraviolet light and ozone by being irradiated with ultraviolet light in an oxygen atmosphere. This method is considered to enable finer roughening than when the desmear treatment, known as the conventional roughening method, is used.

### PRIOR ART DOCUMENT

### Patent Document

Patent Document 1: JP-A-2019-091840

### SUMMARY OF THE INVENTION

### Problems to be Solved by the Invention

However, as a result of verification, the present inventors have found that a base material formed from the resin material easily weakens according to the method of Patent Document 1. In other words, in the case of the method of Patent Document 1, extremely precise control is required to modify the surface without weakening the base material, causing a problem for practical use. In addition, given the above verification, it is considered that a similar problem also occurs when copper foil is bonded and joined using an adhesive.

An object of the present invention is to provide a surface modification method capable of imparting adhesion to the surface of a base material in a more controllable manner than before without substantially providing irregularities on the surface of the base material.

Another object of the present invention is to provide a method for producing a resin plating material in which a plating material is imparted to a resin in a more controllable manner than before without substantially providing irregularities on the surface of the base material. Still, another object of the present invention is to provide an electroless plating apparatus suitable for the use of this method.

### Means for Solving the Problems

A surface modification method according to the present invention includes: a step (a) of preparing a base material containing an insulating resin material; and a step (b) of irradiating the surface of the base material with ultraviolet light having a wavelength of 200 nm or less, in an atmosphere with an oxygen concentration of 0.01 vol % to 10 vol %, to modify a treatment target region including the surface of the base material, into a microporous layer including voids of nanometer (nm) order size.

The present inventors infer the reason why the base material easily weakens with the method described in Patent Document 1 as follows.

Conventionally, when a resin base material is irradiated with ultraviolet light, as schematically illustrated in FIG. 1, it has been considered that the contact angle of the surface of the base material monotonically decreases with respect to the irradiation amount of ultraviolet light. The small contact angle means that when another layer is bonded to the surface of the base material, the adhesive strength between the two increases. Therefore, as schematically illustrated in FIG. 2, it has been considered that the adhesive strength monotonically increases with respect to the irradiation amount of ultraviolet light.

That is, it has been considered that stable bonding of another layer to the surface of the base material can be achieved by irradiating the base material with ultraviolet light that has a larger irradiation amount than a point where a curve indicating the trend of change in contact angle shows an inflection point, that is, an irradiation amount of Q1 or more in FIG. 1.

However, according to intensive studies by the present inventors, it has been confirmed that when the relationship between the irradiation amount and the adhesive strength is measured while the base material is irradiated with ultraviolet light in an ambient atmosphere, as illustrated in FIG. 3, the adhesive strength shows a decreasing trend after reaching a peak value as the irradiation amount increases. FIG. 3 is a graph schematically illustrating the relationship between the irradiation amount of the base material with ultraviolet light and the adhesive strength between the surface of the base material and another layer, which has been newly confirmed by the present inventors.

That is, according to the result of FIG. 3, it is found that the irradiation amount of ultraviolet light needs to be adjusted within a limited irradiation amount range (Qrl) to impart high adhesive strength to the surface of the base material.

FIG. 4 is a graph obtained by actually irradiating the surface of the base material with ultraviolet light at a predetermined intensity under an ambient atmosphere and measuring the relationship between the irradiation time of the ultraviolet light and the contact angle of the surface of the base material and the relationship between the irradiation time and the adhesive strength. In FIG. 4, the horizontal axis represents the irradiation time of ultraviolet light, the left vertical axis represents the adhesive strength, and the right vertical axis represents the contact angle. FIG. 4 is a graph created specifically based on results measured using the following method.

As a sample of the base material, a polyimide resin (Kapton 100EN-C, manufactured by DU PONT-TORAY CO., LTD.) was prepared (Kapton is a registered trademark of the company). The surface of this sample was irradiated with ultraviolet light from a location with an irradiation distance (separation distance) of 3 mm using an ultraviolet irradiation apparatus (manufactured by USHIO INC., SVC 232 Series, peak wavelength 172 nm).

Each sample was irradiated with ultraviolet light while the irradiation time was varied, and then the contact angle of the sample surface was measured using a contact angle measuring apparatus (DMo-501 manufactured by Kyowa Interface Science Co., Ltd.).

Next, each sample was irradiated with ultraviolet light while the irradiation time was varied, and the irradiation surfaces of the same samples were then pasted together with an adhesive sheet (Aron Mighty AF-700 manufactured by Toagosei Company, Limited) placed therebetween, and laminated at 100° C. (“Aron Mighty” is a registered trademark of the company). Thereafter, a pressure bonding process was performed at 180° C. for 30 minutes while pressing was performed at a pressure of 2 MPa to 3 MPa. The adhesive strength of the pasted sample, obtained after the pressure bonding, was measured using a method in accordance with the Japanese Industrial Standards (JIS) K 6854-3 (adhesive-peeling adhesive strength test method, Part 3: T-shaped peeling). However, in FIG. 4, the adhesive strength is shown as a relative value.

According to the results of FIG. 4, it is confirmed that in the graph illustrating the relationship between the adhesive strength and the irradiation time, the adhesive strength shows a decreasing trend as the irradiation time increases after the peak value. When the illuminance of the ultraviolet light is constant, the irradiation time is proportional to the irradiation amount. That is, it can be seen that FIG. 3 schematically illustrates the trend of FIG. 4.

From the results of FIGS. 3 and 4, it can be seen that when the base material is irradiated with ultraviolet light using the conventional method, the condition of the irradiation amount showing high adhesive strength is extremely limited. In other words, it can be seen that high adhesive strength cannot be achieved unless the irradiation amount of ultraviolet light is controlled with extremely high accuracy. According to the results of FIG. 4, it is understood that the adhesive strength decreases with an increase in irradiation time of only about one second to several seconds. However, the relationship between the adhesive strength and the irradiation time (irradiation amount) as illustrated in FIG. 4 is common among resins in terms of the overall trend that the range showing the peak value is narrow, but the relationship varies depending on the resin in terms of what is actually a preferred irradiation amount. Therefore, as a result, the base material is irradiated with ultraviolet light over a preferable irradiation amount, leading to a reduction in the adhesive strength of the surface of the base material.

On the other hand, when attempting to adjust the irradiation time so that the preferable irradiation amount is not exceeded, conversely, the irradiation amount required for the adhesive strength to reach the peak value may not be reached. In this case, as well, high adhesive strength cannot be imparted to the base material.

FIG. 5 is a graph illustrating absorption spectra of oxygen (O₂) and ozone (O₃). In FIG. 5, an emission spectrum of an Xe excimer lamp is superimposed for reference. In FIG. 5, the horizontal axis represents the wavelength, the left vertical axis represents the relative value of light intensity of the excimer lamp, and the right vertical axis represents the absorption coefficients of oxygen (O₂) and ozone (O₃).

Patent Document 1 describes that the wavelength of ultraviolet light is preferably 150 nm to 400 nm, more preferably 150 nm to 350 nm, and still more preferably 150 nm to 300 nm. According to the example of Patent Document 1, an ultraviolet irradiation apparatus (SSP-16: manufactured by SEN LIGHTS Co., Ltd.) is used for the surface treatment of the resin, and it is clear from the company's catalog that this light source exhibits peak values of the emission spectrum at 185 nm and 254 nm. From this, it is understood that in Patent Document 1, a low-pressure mercury lamp is scheduled to be used as the light source for the surface treatment of the base material.

The low-pressure mercury lamp emits ultraviolet light with a peak wavelength having an extremely short half-value width near 185 nm and near 254 nm. As illustrated in FIG. 5, ultraviolet light near 185 nm is easily absorbed by oxygen. Therefore, when the resin base material is irradiated with ultraviolet light from the low-pressure mercury lamp under an ambient atmosphere, a part of ultraviolet light is absorbed by oxygen in the air, and atomic oxygen O(³P) in a ground state is generated according to the following Formula (1).

O₂+hv(185 nm)→O(³P)+O(³P) (1)

This atomic oxygen O(³P) reacts with oxygen (O₂) in the air to generate ozone (O₃) according to the following Formula (2).

O(³P)+O₂→O₃ (2)

As illustrated in FIG. 5, ozone (O₃) exhibits a property of absorbing ultraviolet light. When ultraviolet light from the low-pressure mercury lamp is absorbed by ozone (O₃), atomic oxygen O(¹D) in an excited state is generated according to the following Formula (3).

O₃+hv(185 nm,254 nm)→O₂+O(¹D) (3)

Atomic oxygen O(¹D) has extremely high reactivity. Thus, atomic oxygen O(¹D) acts on the polymer (CₘHₙOₖ) of the resin constituting the base material, thereby cleaving molecular chains. In the following Formula (4), m, m′, n, n, k, and k′, are all integers, and m>m′, n>n′, and k>k′ hold. However, it should be noted that Formula (4) schematically shows a reaction and is different from an accurate chemical reaction formula.

CₘHₙOₖ+0(¹D)→H₂O,CO,CO₂+Cₘ′Hₙ′Oₖ′ (4)

In addition to the action of O(¹D), direct irradiation with ultraviolet light also breaks a part of the binding of the polymer (CₘHₙOₖ) constituting the resin, as well as the intermediate product generated by the reaction of Formula (4).

Since the ultraviolet light emitted from the low-pressure mercury lamp contains a long-wavelength component of 254 nm, the ultraviolet light easily enters the base material in the depth direction, compared to a short-wavelength component of 200 nm or less. Therefore, as illustrated in FIG. 6, a part of ultraviolet light L90 from a low-pressure mercury lamp 90 travels into a base material 3 in the depth direction. That is, energy derived from the ultraviolet light L90 is input to a region from the surface 3a of the base material 3 to a point proceeding by d90 in the depth direction.

Then, due to the above circumstances, the ultraviolet light L90 itself and highly reactive O(¹D) obtained by Formula (3) act on a sufficiently deep location from the surface 3a of the base material 3. As a result, at a location sufficiently deep from the surface 3a of the base material 3, the binding of the polymer (CₘHₙOₖ) constituting the base material 3 is cleaved to lower the molecular weight. As a result, it is considered that molecular chains with small molecular weights enter an overlapped state, leading to the weakening of the base material 3.

FIG. 7 is a view schematically illustrating the molecular chains of the polymer material constituting the base material 3. As described above, when ultraviolet light or mainly O(¹D) acts on the deep location of the base material 3, the molecular chains are cleaved at many locations to generate low-molecular substances (cf. FIG. 8). FIG. 8 schematically illustrates a state where the constituent material of the base material 3 illustrated in FIG. 7 has been cleaved to lower the molecular weight.

That is, since the ultraviolet light L90 emitted from the low-pressure mercury lamp has wavelength components of 185 nm and 254 nm, while modifying the surface 3a of the base material 3, the ultraviolet light L causes damage to the base material 3 in the depth direction due to the long-wavelength component. This results in a reduction in the strength of the base material 3.

Therefore, the present inventors have studied the use of a xenon (Xe) excimer lamp that emits ultraviolet light with a small wavelength component of 200 nm or more as a light source, instead of the low-pressure mercury lamp, and irradiating the base material with ultraviolet light from that light source. However, as described above with reference to FIG. 4, the irradiation amount of ultraviolet light that can impart high adhesive strength to the base material is limited.

The present inventors considered that the reason why the irradiation amount of ultraviolet light that can impart high adhesive strength to the base material is limited as described above is that the reaction proceeds at an extremely high rate. In particular, in the case of ultraviolet light with a peak wavelength of less than 185 nm as in a Xe excimer lamp (the peak wavelength is near 172 nm), when a part of ultraviolet light is absorbed by oxygen in the air, atomic oxygen O(¹D) in an excited state is generated according to the following Formula (5).

O₂+hv(172 nm)→O(¹D)+O(³P) (5)

Note that a part of the atomic oxygen O(³P) obtained by Formula (5) changes to the atomic oxygen O(¹D) in the excited state through the formulas (2) and (3) as described above.

That is, as the ultraviolet light, with which the base material is irradiated, has a shorter wavelength, only the surface layer of the base material reacts, and there is little damage in the depth direction, so that the generation rate of highly reactive O(¹D) increases. This is considered to increase the rate at which the molecular chains of the polymer material constituting the base material are cleaved.

To efficiently modify the surface of the base material, it is preferable to cleave only the molecular chains of the polymer material present near the surface of the base material and generate voids by the cleavage. This is because, when an adhesive is applied or a catalyst is applied for subsequent bonding of another layer, a compound (hereinafter referred to as a “catalyst contributing compound”) containing the constituent material of the adhesive or molecules or atoms exhibiting a catalytic effect can enter the voids. However, as described above, when the reaction of cleaving the molecular chains of the polymer material proceeds at a high rate, a similar phenomenon occurs not only on the surface of the base material but also in a deep region, leading to the weakening of the base material. That is, the limited amount of irradiation with which high adhesive strength can be imparted to the base material as described above with reference to FIGS. 3 to 4 can be said to be an amount of irradiation with which only the molecular chains of the polymer material present near the surface of the base material can be cleaved.

In the method according to the present invention, the atmosphere irradiated with ultraviolet light is set to 0.01 vol % to 10 vol %, and the oxygen concentration is set to be extremely low compared to the air. This reduces the generation rate of O(¹D) to expand the range of the irradiation amount that can impart high adhesive strength to the base material, thereby increasing the flexibility in control and improving controllability. Note that the term “control” as used herein means control performed to achieve a production process capable of obtaining stable adhesive strength (including plating strength).

FIG. 9 is a graph schematically illustrating, in the same manner as FIG. 3, the relationship between the irradiation amount of the base material with ultraviolet light and the adhesive strength between the surface of the base material and another layer when the atmosphere is set to a low oxygen concentration. FIG. 9 illustrates a graph of the result in the ambient atmosphere overlaid for comparison.

According to the result of FIG. 9, it is found that when the atmosphere is set to a low oxygen concentration, the range (Qr2) of the irradiation amount of ultraviolet light that can impart high adhesive strength to the surface of the base material is greatly expanded compared to the case (Qrl) of the ambient atmosphere. Then, by irradiating the base material with ultraviolet light at an irradiation amount in this range (Qr2), polymer chains near the surface of the base material are cleaved, and voids are formed. That is, only the vicinity of the surface of the base material is modified to a layer including voids (microporous layer).

FIG. 10 is a graph obtained by actually irradiating the surface of the base material with ultraviolet light at a predetermined intensity under a low oxygen atmosphere, and measuring the relationship between the irradiation time of the ultraviolet light and the contact angle of the surface of the base material and the relationship between the irradiation time and the adhesive strength. The graphing method is common to FIG. 4 except that the oxygen concentration of the atmosphere is different. In FIG. 10, the oxygen concentration of the atmosphere was 0.1 vol % (1000 ppm).

According to the result of FIG. 10, it is confirmed that the adhesive strength does not decrease much compared to FIG. 4 even with irradiation with ultraviolet light for about several tens of seconds to 100 seconds longer than the irradiation time during which the adhesive strength shows the peak value. That is, it can be seen that FIG. 10 schematically illustrates the trend of FIG. 9.

FIG. 11 is a view schematically illustrating the traveling state of ultraviolet light L10 when the base material 3 is irradiated with the ultraviolet light L10 from an Xe excimer lamp 10, in the same manner as in FIG. 6. The ultraviolet light L10 from the Xe excimer lamp 10 has a peak wavelength near 172 nm. As illustrated in FIG. 11, the ultraviolet light L10 travels a distance d10 in the depth direction from the surface of the base material 3. The ultraviolet light L10 from the Xe excimer lamp 10 has a wavelength band shorter than that of the ultraviolet light L90 emitted from the low-pressure mercury lamp. Therefore, the distance d10 is extremely short compared to the travel distance d90 (FIG. 6) measured in the case of irradiation with ultraviolet light L90 from the low-pressure mercury lamp 90. That is, the ultraviolet light L10 acts only on the vicinity of the surface of the base material 3.

When an atmosphere 1 irradiated with the ultraviolet light L10 has a low oxygen concentration, as described above, the range of the irradiation amount of ultraviolet light L10 that can impart high adhesive strength to the surface 3a of the base material 3 is expanded. When the surface 3a of the base material 3 is irradiated with the ultraviolet light L10 at such an irradiation amount, only some of the polymer chains constituting the base material 3 are cleaved and oligomerized. At this time, a space (void 4) is formed between oligomers (cf. FIG. 12). FIG. 12 schematically illustrates a state where some of the polymer chains constituting the base material 3 are cleaved to form the voids 4, in the same manner as FIG. 8.

By forming the voids 4 near the surface 3a of the base material 3, constituent molecules of the adhesive and the catalyst contributing compound can enter the voids 4. As a result, high adhesive strength can be imparted to the surface 3a of the base material 3 without roughening the surface 3a of the base material 3.

That is, in the present specification, the “microporous layer” is a layer including the voids 4 generated by cleaving some of the polymer chains constituting the base material 3, and the voids 4 are of nm order size (1 nm to several nm).

The presence and thickness of the microporous layer can be confirmed by bonding another layer to the surface of the base material and then observing the cross section with a transmission electron microscope (TEM). Details will be described later.

In the above description, the case where the peak wavelength of the ultraviolet light is near 172 nm has been exemplified, but the same description can be made for the case of 200 nm or less. In the case of ultraviolet light with a wavelength longer than 172 nm 10 and 200 nm or less, the generation rate of atomic oxygen O(¹D) is expected to be slightly slower than that of ultraviolet light with a peak wavelength of 172 nm. However, in the case of irradiation in the ambient atmosphere, as in the case of the wavelength of 172 nm, when the irradiation time increases by several seconds, the adhesive strength decreases significantly. However, when the wavelength of the ultraviolet light exceeds 200 nm, the proportion of the ultraviolet light traveling in the depth direction of the base material is gradually increased for the reasons described above, and the base material tends to be weakened.

The treatment target region may be a region between the surface and a location proceeding 3 nm to 50 nm from the surface in a depth direction orthogonal to the surface.

After the step (b), another layer may be bonded to the surface of the base material through a catalyst. As described above, by forming the microporous layer near the surface of the base material, the catalyst contributing compound is incorporated into the voids in the microporous layer, and high adhesive force is achieved. Since the outer diameter of the catalyst contributing compound is about 3 nm, when the thickness of the treatment target region is less than 3 nm, the catalyst contributing compound does not sufficiently enter the voids, and the action of increasing the adhesive force is limited.

In addition, at a location proceeding 50 nm or more in the depth direction from the surface, the action exerts in a direction of weakening the base material itself, resulting in a reduction in adhesive strength.

The surface modification method may further include a step (c) of removing a low-molecular-weight component contained in the base material after the step (b).

As described above, when the base material is irradiated with ultraviolet light, the polymer constituting the base material is cleaved due to the ultraviolet light itself or the atomic oxygen O(¹D). In this process, molecular chains with an extremely low molecular weight compared to that of the resin constituting the base material may be secondarily generated. When a catalyst or an adhesive is introduced after the step (b), the catalyst or the adhesive is incorporated into the low molecular chains. However, the catalyst and the adhesive incorporated into the low molecular chains do not contribute to the improvement of the adhesive strength.

As described above, by performing the step (c) of removing a low-molecular-weight component contained in the base material, most of the catalyst and the adhesive to be introduced thereafter can be incorporated into the voids in the microporous layer. That is, according to this method, it is possible to achieve high adhesive strength while reducing the amount of the catalyst and the adhesive used.

Examples of the step (c) of removing a low-molecular-weight component include an alkaline cleaning treatment, a warm water cleaning treatment, and a drying treatment. Among these, the alkaline cleaning treatment is particularly preferred.

That is, the step (c) may be a step of immersing the base material in an alkaline solution after execution of the step (b).

The type of the alkaline solution used in this step is not particularly limited, but for example, one or more types belonging to the group consisting of sodium hydroxide, lithium hydroxide, and potassium hydroxide can be suitably used.

The step (a) may include a step of placing the base material on a conveyance path. The step (b) may include a step of irradiating the base material with the ultraviolet light from an ultraviolet light source in a treatment space where the ultraviolet light source is accommodated, while conveying the base material. A nitrogen gas may be introduced into the treatment space during the execution of the step (b). The step (b) may end at the latest at a point when the base material passes through the treatment space.

The step (a) may include a step of placing the base material at a predetermined location in a chamber. The step (b) may include a step of closing a space that includes the predetermined location in the chamber in a state where the space is set to an atmosphere including a mixed gas that contains oxygen with a concentration of 0.01 vol % to 10 vol % and nitrogen, and then irradiating the base material with the ultraviolet light from an ultraviolet light source installed in the chamber.

A method for producing a resin plating material according to the present invention includes the surface modification method, and includes: a step (d) of binding a catalyst to the microporous layer after the step (a) and the step (b); and a step (e) of forming an electroless plating layer on an upper surface of the base material through the catalyst after the step (d).

When the plating layer is formed on the upper surface of the base material, it is important to enhance the adhesion between the base material and the plating layer. In terms of enhancing the adhesion between the base material and the layer thereon, the problem is common between the case of forming an adhesive layer (adhesive sheet) on the upper layer of the base material and the case of forming a plating layer on the upper layer of the base material. The problem that may occur when the adhesive sheet is formed on the base material is as described above. That is, the base material is irradiated with ultraviolet light exceeding a preferable irradiation amount, leading to a reduction in the adhesive strength of the surface of the base material. In contrast, when attempting to adjust the irradiation time so as not to exceed the preferable irradiation amount, conversely, the irradiation amount required for the adhesive strength to reach the peak value may not be reached, and even in this case, the high adhesive strength cannot be imparted to the base material.

It is understood that the above problem can also occur similarly when the surface of the base material is irradiated with ultraviolet light to achieve high adhesion when the plating layer is formed on the upper surface of the base material. That is, when the base material is irradiated with ultraviolet light to form the plating layer on the upper surface of the base material, there is a concern that the adhesive strength of the surface of the base material is reduced by irradiating the base material with ultraviolet light exceeding a preferable irradiation amount. In addition, when attempting to adjust the irradiation time so that the preferable irradiation amount is not exceeded, conversely, the irradiation amount required for the adhesive strength to reach the peak value may not be reached.

As described above, as a result of performing the steps (a) and (b), the voids 4 are formed near the surface 3a of the base material 3. Therefore, by executing the step (d) of acting the catalyst thereafter, the catalyst contributing compound can enter the voids 4 without roughening the surface 3a of the base material 3. Therefore, by performing the step (e) of forming an electroless plating layer thereafter, an electroless plating layer with high adhesion to the surface 3a of the base material 3 is formed.

In the step (d), any method can be used as long as the method enables the catalyst contributing compound to enter the microporous layer. As a typical example, a step of adjusting the surface potential of the base material as necessary and then immersing the base material in a chemical solution containing the catalyst contributing compound is employed. Thereafter, an activation treatment is performed as necessary.

In the step (e), any method can be used as long as the step enables the formation of an electroless plating layer on the upper surface of the base material in a state where the catalyst contributing compound is bound to the microporous layer. As atypical example, a step of immersing the base material in an electroless metal plating solution after execution of the step (d) is employed.

That is, the method for producing a resin plating material according to the present invention enables the production of a resin plating material that exhibits a stable adhesive force between the base material and the plating material, even though the method is difficult to substantially form irregularities on the surface of the base material.

In the method for producing a resin plating material, vibration by ultrasonic waves may be imparted during the execution of the step (e).

A conventionally known method is to reduce Ni ions with sodium hypophosphite, using palladium (Pd) as a catalyst, thereby forming an electroless Ni film (electroless plating layer) on the resin surface. This method is a method in which a base material including a surface to which Pd particles as a catalyst are attached is immersed in an electroless plating solution to form an electroless plating layer made of Ni₂P on the resin surface through reaction mechanisms of the following formulas (6) to (8).

H₂PO²⁻+H₂O→HPO₃²⁻+H⁺+(1/2)H₂+e⁻ (6)

Ni²⁺+2e⁻→2Ni (7)

2Ni²⁺H₂PO₂⁻+2H⁺+5e⁻→Ni₂P+2H₂O (8)

However, as a result of intensive studies by the present inventors, it has been found that fine holes (pinholes) exist at an interface between the electroless plating layer formed by the conventional electroless plating method and the base material, causing a plating defect. The present inventors infer that the cause of this is as follows.

According to the above Formula (6), hydrogen (H₂) is inevitably generated in the process of the reaction. Therefore, during the step of immersing the base material in the electroless plating solution, bubbles derived from hydrogen gas are generated and adhere to the surface of the base material. When the electroless plating layer is formed on the surface of the base material in this state, the electroless plating layer is formed while bubbles remain on the surface of the base material. As a result, pinholes derived from the bubbles are formed in the obtained resin plating material, causing a plating defect.

As a result of intensive studies by the present inventors, it has been confirmed that fine pinholes may also be generated in the resin plating material produced through the above steps (a), (b), (d), and (e). From this point as well, it is inferred that the cause of the generation of pinholes is irrelevant to irradiation with ultraviolet light.

In contrast, according to the above method, since vibration due to ultrasonic waves is imparted at the time of forming the electroless plating layer, bubbles derived from hydrogen gas adhering to the surface of the base material can be separated from the base material. This makes it possible to further improve the adhesion between the base material and the electroless plating layer.

The treatment target region may be a region between the surface and a location proceeding 3 nm to 50 nm from the surface in a depth direction orthogonal to the surface.

As described above, after the step (b), the step (d) of binding the catalyst to the microporous layer is performed. The outer diameter of the compound (catalyst contributing compound) containing molecules or atoms exhibiting a catalytic effect is about 3 nm. Therefore, when the thickness of the treatment target region is less than 3 nm, the catalyst contributing compound does not sufficiently enter the voids, limiting the action of enhancing the adhesive force. On the other hand, at a place proceeding 50 nm or more in the depth direction from the surface, the action exerts in a direction of weakening the base material itself, resulting in a reduction in the adhesive strength between the resin and the plating layer.

The method for producing a resin plating material may further include a step (c) of removing a low-molecular-weight component contained in the base material after the step (b) and before the step (d). This step (c) is common to the step (c) described above in the section of the surface modification method.

That is, examples of the step (c) of removing a low-molecular-weight component include an alkaline cleaning treatment, a warm water cleaning treatment, and a drying treatment. Among these, the alkaline cleaning treatment is particularly preferred. In other words, the step (c) may be a step of immersing the base material after execution of the step (b) in an alkaline solution.

Further, an electroless plating apparatus according to the present invention includes: a pretreatment unit that irradiates a base material containing an insulating resin material with ultraviolet light having a wavelength of 200 nm or less; a catalyst treatment unit that includes a first storage tank storing a solution containing a catalyst, and in which the base material, after being irradiated with the ultraviolet light by the pretreatment unit, is positioned in the first storage tank; and a plating treatment unit that includes a second storage tank storing a plating solution, and in which the base material, after being removed from the catalyst treatment unit, is positioned in the second storage tank. The pretreatment unit includes a nitrogen gas source, and irradiates the base material, positioned in an irradiation region irradiated with the ultraviolet light from the nitrogen gas source, with the ultraviolet light in a state where an oxygen concentration of an atmosphere in the irradiation region is adjusted to 0.01 vol % to 10 vol % by introducing nitrogen into the irradiation region.

According to the electroless plating apparatus, the plating layer can be formed on the surface of the base material in the state of having high adhesion without forming substantial irregularities on the surface of the base material, while increasing the flexibility in controlling the irradiation amount of the base material with ultraviolet light in the pretreatment unit.

The plating treatment unit may include an ultrasonic wave generator capable of transmitting ultrasonic waves to the plating solution in the second storage tank, and the base material, after being removed from the catalyst treatment unit, may be positioned in the second storage tank in a state where the ultrasonic wave, generated by the ultrasonic wave generator, is transmitted to the plating solution.

The electroless plating apparatus may include a conveyance path that connects the pretreatment unit, the catalyst treatment unit, and the plating treatment unit. The respective treatments in the pretreatment unit, the catalyst treatment unit, and the plating treatment unit may be executed while the base material moves on the conveyance path.

### Effect of the Invention

According to the present invention, it is possible to impart adhesion to the surface of the base material without providing substantial irregularities on the surface of the base material in a more controllable manner than before. In addition, it is possible to produce a resin plating material obtained by imparting a plating material to the surface of the base material in a more controllable manner than before without providing substantial irregularities on the surface of the base material.

### BRIEF DESCRIPTION OF THE DRAWINGS

FIG. 1 is a graph schematically illustrating the relationship between an irradiation amount of a base material with ultraviolet light and a contact angle of the surface of the base material, which has been conventionally assumed.

FIG. 2 is a graph schematically illustrating the relationship between the irradiation amount of the base material with ultraviolet light and the adhesive strength between the surface of the base material and another layer, which has been conventionally assumed.

FIG. 3 is a graph schematically illustrating the relationship between an irradiation amount of a base material with ultraviolet light under an ambient atmosphere and the adhesive strength between the surface of the base material and another layer derived from the verification of the present inventors.

FIG. 4 is a graph illustrating the relationship between the irradiation time of ultraviolet light and the contact angle of the surface of the base material and the relationship between the irradiation time and adhesive strength when the surface of the base material is irradiated with ultraviolet light at a predetermined intensity under the ambient atmosphere.

FIG. 5 is a graph illustrating an emission spectrum of an Xe excimer lamp overlaid on absorption spectra of oxygen (O₂) and ozone (O₃).

FIG. 6 is a view schematically illustrating a traveling state of ultraviolet light when the base material is irradiated with ultraviolet light from a low-pressure mercury lamp.

FIG. 7 is a view schematically illustrating molecular chains of a polymer material constituting the base material.

FIG. 8 is a view schematically illustrating a state where the molecular chains of the polymer material constituting the base material have been greatly cleaved to lower the molecular weight.

FIG. 9 is a graph schematically illustrating the relationship between the irradiation amount of the base material with ultraviolet light and the adhesive strength between the surface of the base material and another layer when the atmosphere is set to a low oxygen concentration.

FIG. 10 is a graph illustrating the relationship between the irradiation time of ultraviolet light and the contact angle of the surface of the base material and the relationship between the irradiation time and the adhesive strength when the surface of the base material is irradiated with ultraviolet light at a predetermined intensity under a low oxygen atmosphere.

FIG. 11 is a view schematically illustrating a traveling state of ultraviolet light when the base material is irradiated with ultraviolet light from an Xe excimer lamp.

FIG. 12 is a view schematically illustrating a state where some of the molecular chains of a polymer material constituting a base material are cleaved to form voids.

FIG. 13 is a cross-sectional view schematically illustrating a configuration example of a system for carrying out a surface modification method of the present invention.

FIG. 14 is a cross-sectional view schematically illustrating another configuration example of the system for carrying out the surface modification method of the present invention.

FIG. 15 is a cross-sectional view schematically illustrating another configuration example of the system for carrying out the surface modification method of the present invention.

FIG. 16 is a functional block diagram schematically illustrating a configuration of an electroless plating apparatus according to the present invention.

FIG. 17 is a block diagram schematically illustrating a configuration of an embodiment of the electroless plating apparatus.

FIG. 18 is a block diagram schematically illustrating a configuration of another embodiment of the electroless plating apparatus.

FIG. 19 is a cross-sectional view schematically illustrating a configuration example of a pretreatment unit.

FIG. 20 is a cross-sectional view schematically illustrating another configuration example of the pretreatment unit.

FIG. 21 is a cross-sectional view schematically illustrating another configuration example of the pretreatment unit.

FIG. 22 is a graph illustrating the relationship between the irradiation time of ultraviolet light and the peak value of adhesive strength for each oxygen concentration in the atmosphere when the surface of the base material is irradiated with ultraviolet light at a predetermined intensity.

FIG. 23 is a graph for describing a “ratio” that serves as an index for evaluating the level of controllability.

FIG. 24 is a cross-sectional view schematically illustrating a state where an electroless plating layer is formed on a surface of a base material on which a microporous layer is formed.

FIG. 25 is a graph illustrating a result of analyzing the base material with the electroless plating layer formed on the upper surface thereof by transmission electron microscope-energy dispersive X-ray spectroscopy (TEM-EDS) during traveling from an interface with the electroless plating layer toward the base material in a depth direction.

FIG. 26 is a graph illustrating a result of performing mass spectrometry for a substance with a molecular weight lower than that of the constituent material of the base material by time-of-flight secondary ion mass spectrometry (TOF-SIMS) on each of a base material irradiated with ultraviolet light and an unirradiated base material.

FIG. 27A is a graph illustrating results of performing a micro slurry-jet erosion (MSE) test on the base material irradiated with ultraviolet light and the unirradiated base material, respectively.

FIG. 27B is a graph in which approximate lines are added to the results of FIG. 27A.

FIG. 28 is a graph comparing the adhesive strength of the surface of the base material with and without alkaline cleaning on the base material after being irradiated with ultraviolet light.

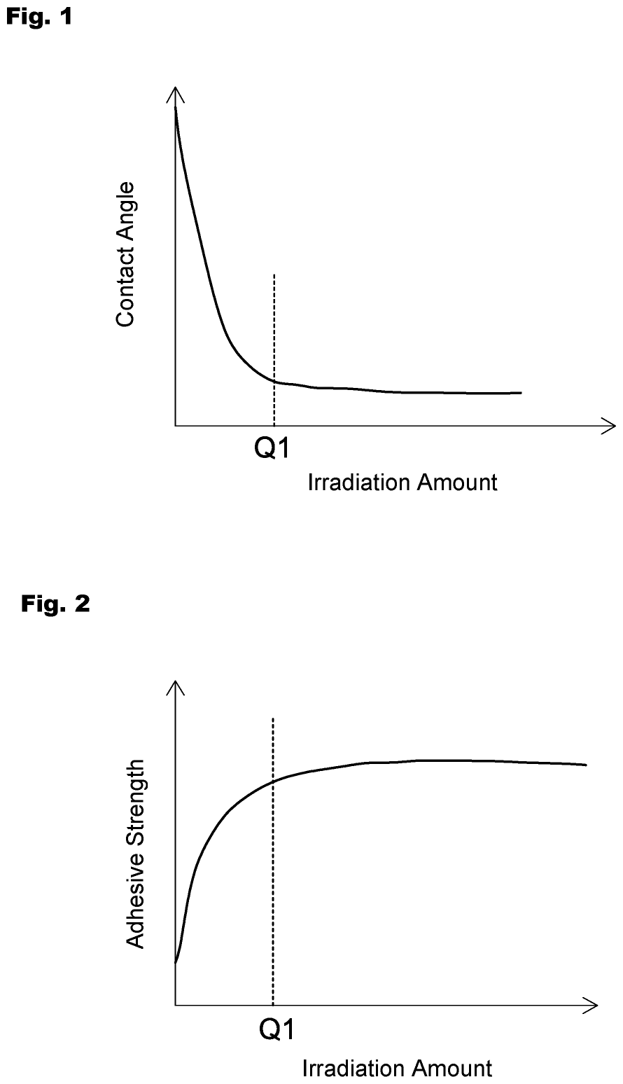

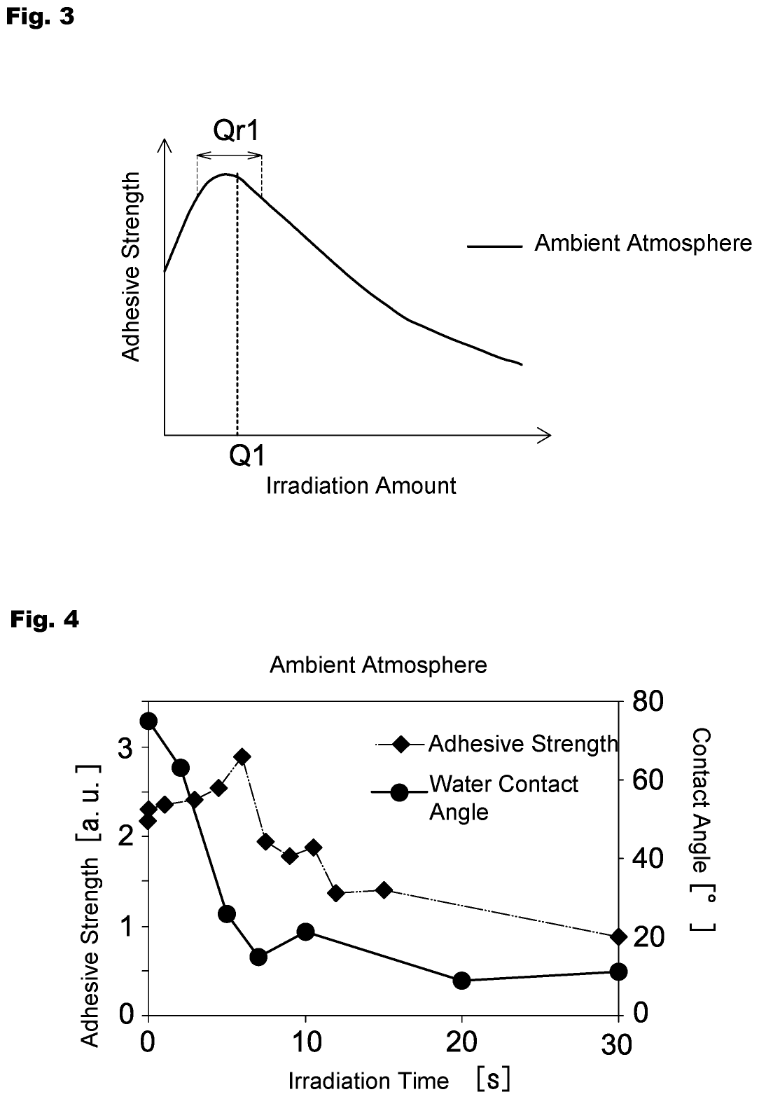

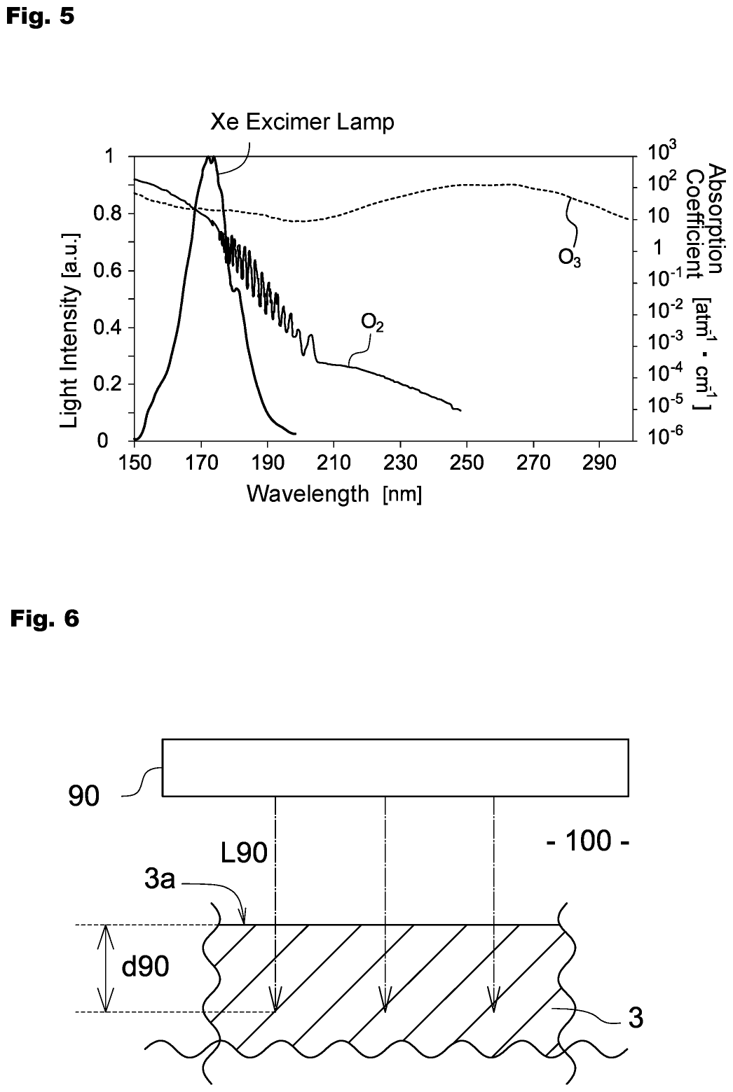

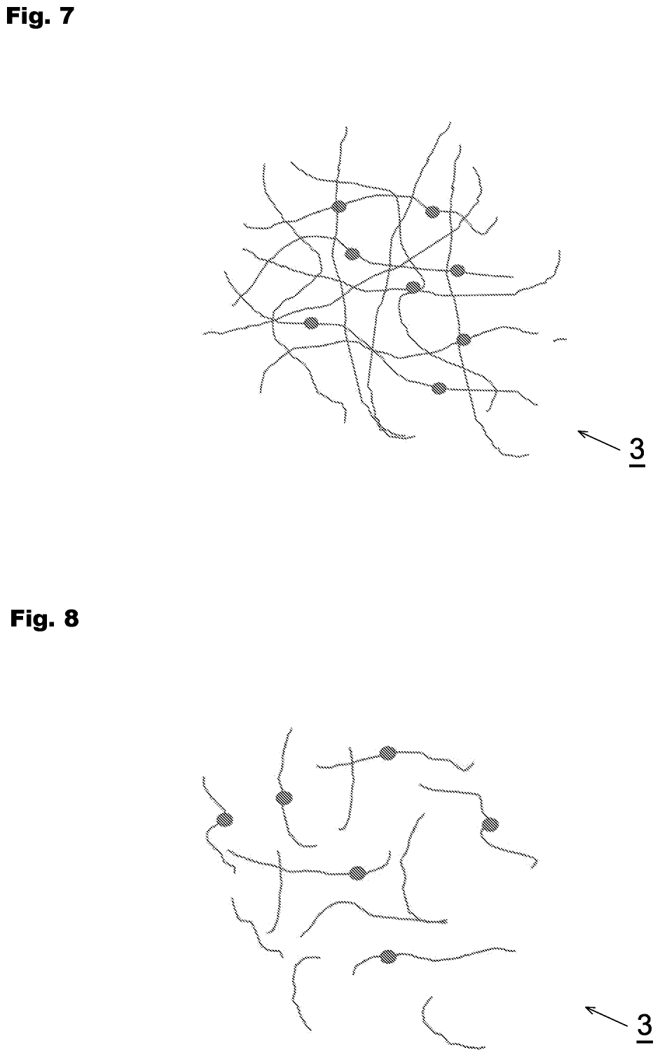

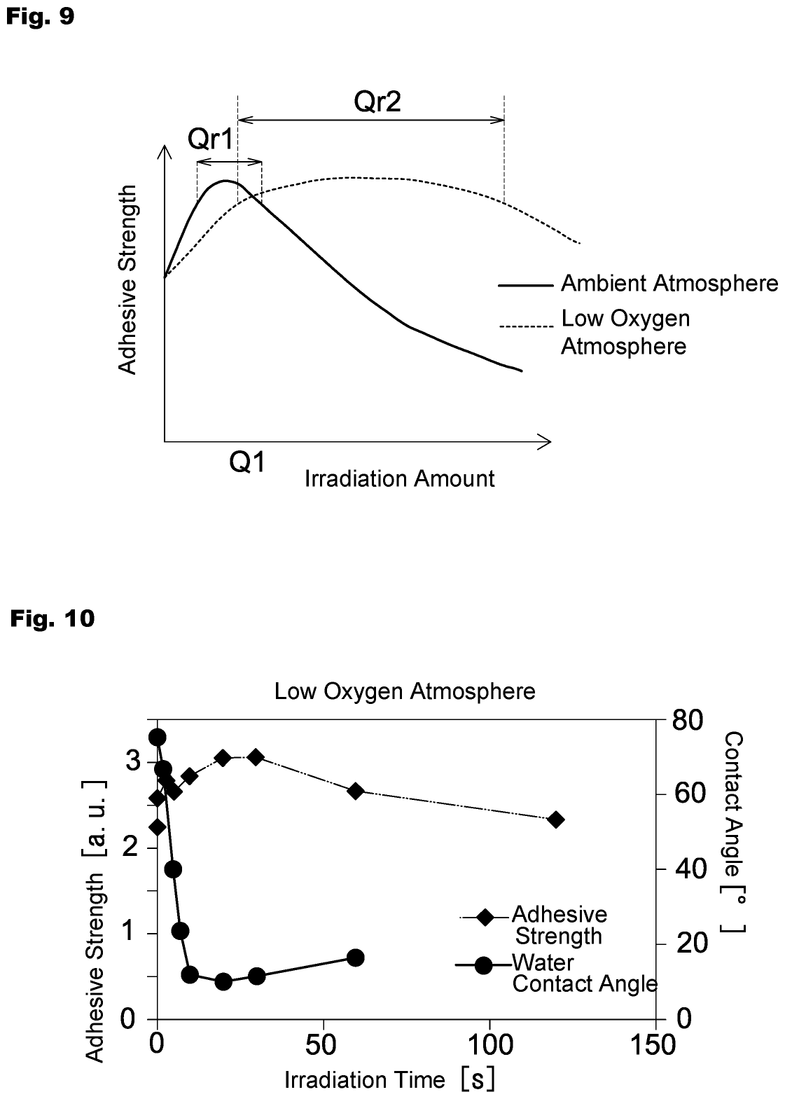

### MODE FOR CARRYING OUT THE INVENTION

[Surface modification method]

Hereinafter, an embodiment of a surface modification method according to the present invention will be described with reference to the drawings as appropriate. However, the following drawings are schematically illustrated, and the dimensional ratios in the drawings do not necessarily coincide with the actual dimensional ratios. In addition, the dimensional ratios may not coincide with each other between the drawings.

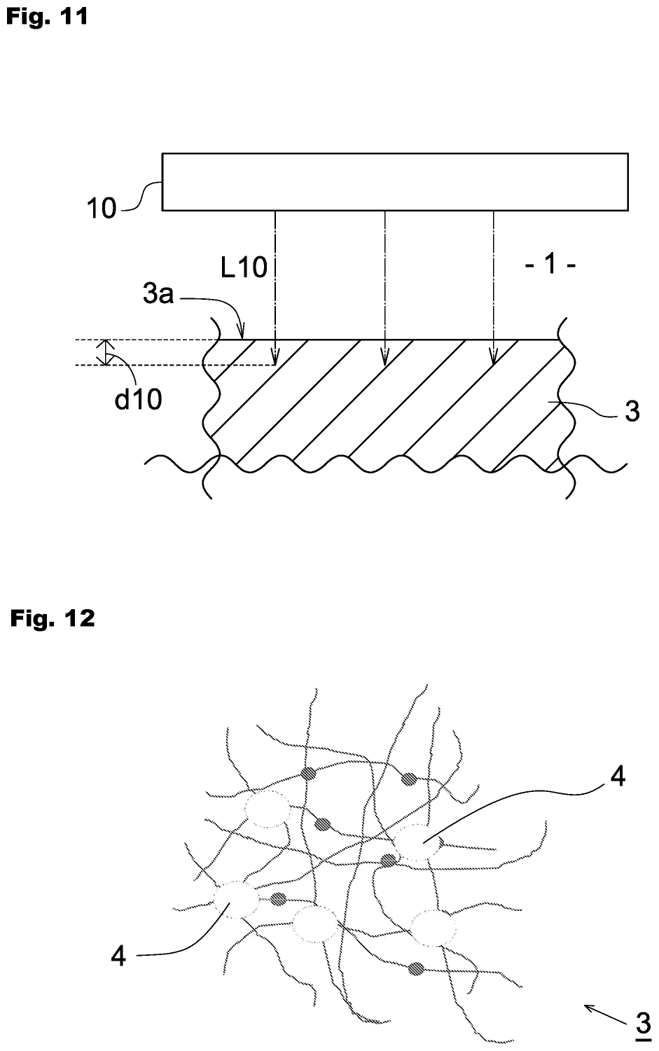

In the following drawings, the same elements as those in FIG. 11 are denoted by the same reference numerals, and the description thereof is simplified.

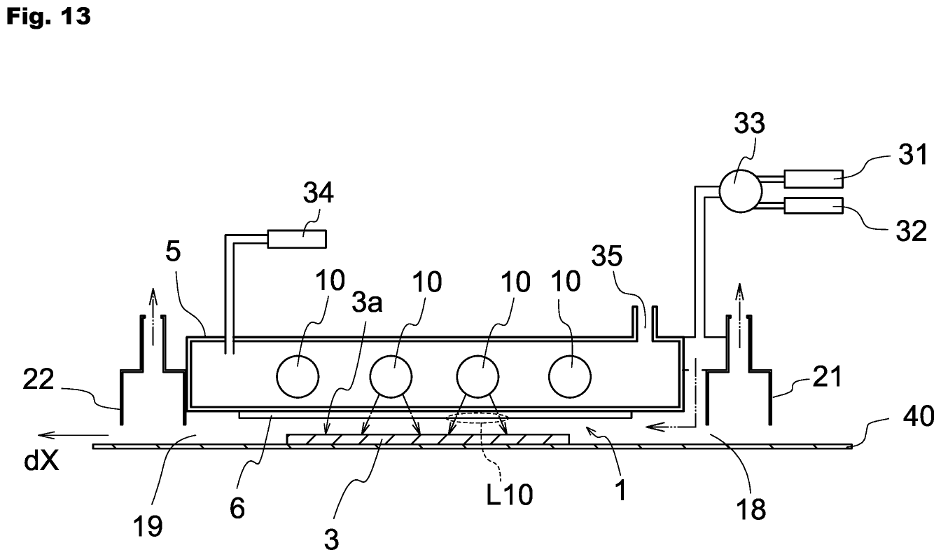

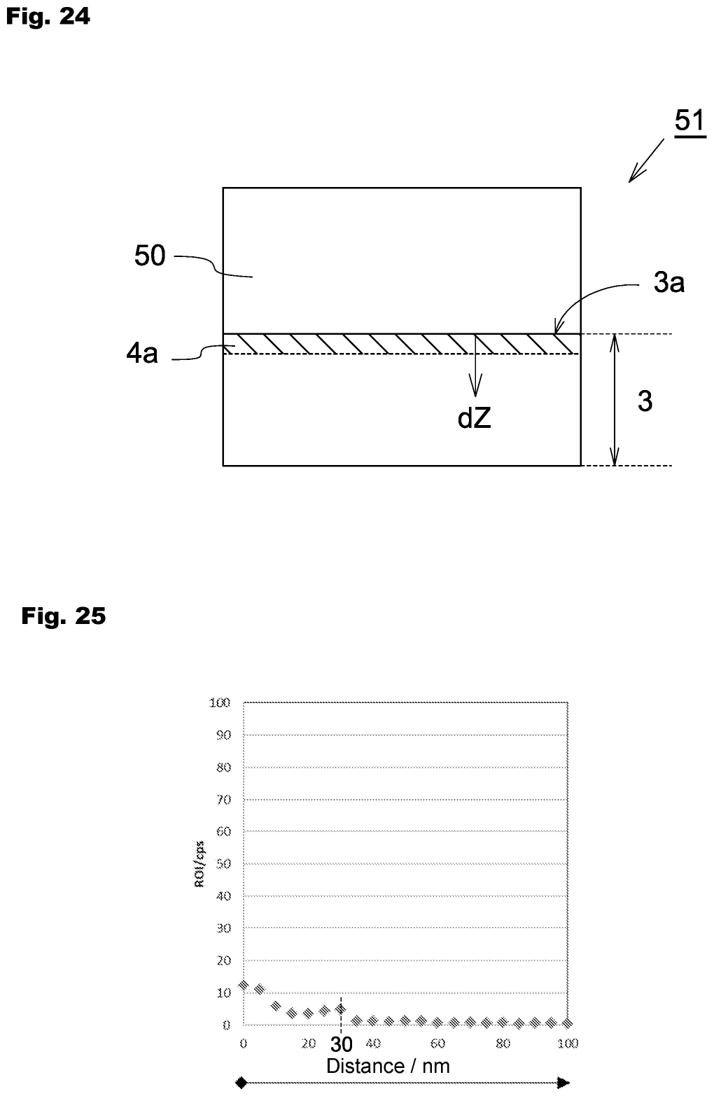

The surface modification method according to the present invention includes: a step (a) of preparing a base material 3 containing an insulating resin material, and a step (b) of irradiating the surface of the base material 3 with ultraviolet light L10 having a wavelength of 200 nm or less in an atmosphere 1 with an oxygen concentration of 0.01 vol % to 10 vol %. This step (b) is a step of modifying a treatment target region (a region within a depth d10), including a surface 3a of the base material 3, into a microporous layer 4a (cf. FIG. 24) that includes voids 4 (cf. FIG. 12) of nm order size.

The type of the base material 3 is not limited as long as the base material 3 is an insulating resin material, and examples thereof include a polyimide resin, a liquid crystal polymer, polystyrene, polyphenylene sulfide, polyether ether ketone, polyethylene naphthalate, a cycloolefin polymer, a cyclic olefin copolymer, polytetrafluoroethylene, and an epoxy-based resin. The base material 3 may be a sheet-like film or a plate-like member.

FIG. 13 is a diagram schematically illustrating a configuration example of a system for carrying out the surface modification method according to the present invention. This system 2 conveys the base material 3 to be treated along the conveyance path 40 and also performs surface treatment of the base material 3.

The system 2 includes a light source apparatus 5 including an Xe excimer lamp 10. The light source apparatus 5 is provided with an irradiation window 6, and the ultraviolet light L10 from the Xe excimer lamp 10 irradiates a conveyance path 40 side through the irradiation window 6. The material of the irradiation window 6 is not limited as long as the material is a member that transmits the ultraviolet light L10, and the irradiation window 6 is made of, for example, synthetic quartz glass. In the light source apparatus 5, nitrogen gas may be sealed in the space where the Xe excimer lamp 10 is installed. In the example illustrated in FIG. 13, nitrogen gas is introduced from a nitrogen gas source 34 into the space where the excimer lamp 10 is installed. In this example, it is assumed that an exhaust port 35 is provided, and the nitrogen gas is caused to constantly flow from the nitrogen gas source 34 during the treatment. However, this aspect is merely an example.

The base material 3 placed on the conveyance path 40 is inserted inside through a loading port 18 while moving in a dX direction along the conveyance path 40, and approaches a location facing the irradiation window 6. Thereafter, the base material 3 is irradiated with the ultraviolet light L10 through the irradiation window 6 while further moving in the dX direction, and removed from an unloading port 19 to the outside.

When the base material 3 is a plate-like body, the conveyance path 40 can employ, for example, a structure including a plurality of conveyance rollers. When the base material 3 is a sheet-like film, the conveyance path 40 may have a structure in which a sheet-like film is stretched between an unwinding roll and a winding roll and wound from the unwinding roll to the winding roll, for example.

The light source apparatus 5 is disposed at a position where the irradiation window 6 is close to the base material 3 on the conveyance path 40 in the optical axis direction of the ultraviolet light L10. Specifically, the separation distance between the irradiation window 6 and the base material 3 is preferably 1 mm to 50 mm, and more preferably 2 mm to 10 mm.

Here, the ultraviolet light source included in the light source apparatus 5 will be described as the Xe excimer lamp 10. However, the light source is not limited to the Xe excimer lamp 10 as long as the light source emits ultraviolet light with a peak wavelength of 200 nm or less, as described above. For example, the light source may be a solid-state light source such as a light-emitting diode (LED) or a laser diode.

The system 2 includes a nitrogen gas source 31, an oxygen-containing gas source 32 and a gas mixer 33. The nitrogen gas source 31 is a gas source sealed with nitrogen gas. The oxygen-containing gas source 32 is a gas source sealed with a gas containing oxygen, typically clear dry air (CDA) as an example. The gas mixer 33 mixes the nitrogen gas from the nitrogen gas source 31 and the oxygen-containing gas from the oxygen-containing gas source 32 while adjusting the flow ratio to generate and deliver a treatment space gas. The treatment space gas delivered from the gas mixer 33 constitutes the atmosphere 1 of the base material 3. FIG. 13 illustrates a case where the flow direction of the treatment space gas is the same as the flow direction (dX direction) of the base material 3, but the flow direction may be reversed. That is, the treatment space gas including the mixed gas of the nitrogen gas from the nitrogen gas source 31 and the oxygen-containing gas from the oxygen-containing gas source 32 may be introduced against the flow of the base material 3, in other words, from the downstream side to the upstream side in the conveyance direction in the conveyance path 40.

As described above, when the system 2 includes the nitrogen gas source 34, the nitrogen gas source 34 may be shared with the nitrogen gas source 31.

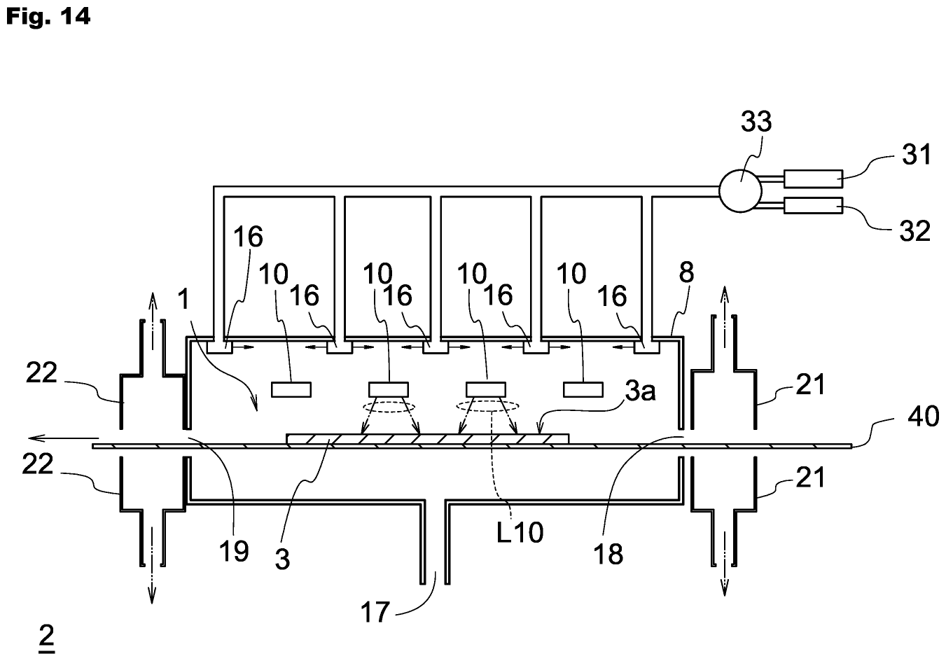

Note that an oxygen concentration detector (not illustrated) may be installed in the space through which the base material 3 passes, and the gas mixer 33 may be feedback-controlled so that the oxygen concentration in the atmosphere 1 in the space is at a predetermined constant value. The same applies to a system 2 illustrated in FIG. 14 to be described later.

In the gas mixer 33, the mixing ratio is adjusted so that the atmosphere 1 of the base material 3 has a low oxygen concentration. Specifically, the oxygen concentration of the atmosphere 1 is 0.01 vol % to 10 vol %, more preferably 0.01 vol % to 5 vol %, and particularly preferably 0.1 vol % to 5 vol %.

The system 2 preferably includes sub-chambers 21 and 22. The sub-chambers 21 and 22 forcibly exhaust gas leaking from the treatment space through the loading port 18 or the unloading port 19 to the outside.

According to the present system 2, the base material 3 is irradiated with the ultraviolet light L10 while moving on the conveyance path 40, whereby the region near the surface of the base material 3 is modified to the microporous layer 4a (cf. FIG. 24) including the voids 4 (cf. FIG. 12).

In the configuration of the system 2 illustrated in FIG. 13, the space (light source apparatus 5) in which the Xe excimer lamp 10 is accommodated and the space through which the base material 3 passes have been separated. However, as illustrated in FIG. 14, both may be arranged in the same space (treatment space 8). FIG. 14 is a view schematically illustrating another configuration example of the system for carrying out the surface modification method according to the present invention, in the same manner as FIG. 13.

In the system 2 illustrated in FIG. 14, the treatment space gas delivered from the gas mixer 33 is supplied into the treatment space 8 through a gas supply pipe 16. In the case of the system 2 illustrated in FIG. 14, it is preferable to provide a gas discharge port 17 for forcibly discharging the gas in the treatment space 8 to the outside. At the start of the treatment, the gas in the treatment space 8 is once discharged through the gas discharge port 17, and then the mixed gas with a low oxygen concentration delivered from the gas mixer 33 is supplied into the treatment space 8 through the gas supply pipe 16, enabling the atmosphere 1 of the base material 3 to have a low oxygen concentration.

In this case, as illustrated in FIG. 14, it is preferable to provide the sub-chambers 21 and 22 at two locations, upper and lower, to sandwich the conveyance path 40.

The base material 3 is not necessarily subjected to surface treatment while being conveyed. That is, even in the case of the system 2 illustrated in each of FIGS. 13 and 14, the base material 3 may be conveyed to a location for irradiation with the ultraviolet light L10 from the Xe excimer lamp 10. Thereafter, the base material 3 may be irradiated with the ultraviolet light L10 in a state where the conveyance path 40 is temporarily stopped.

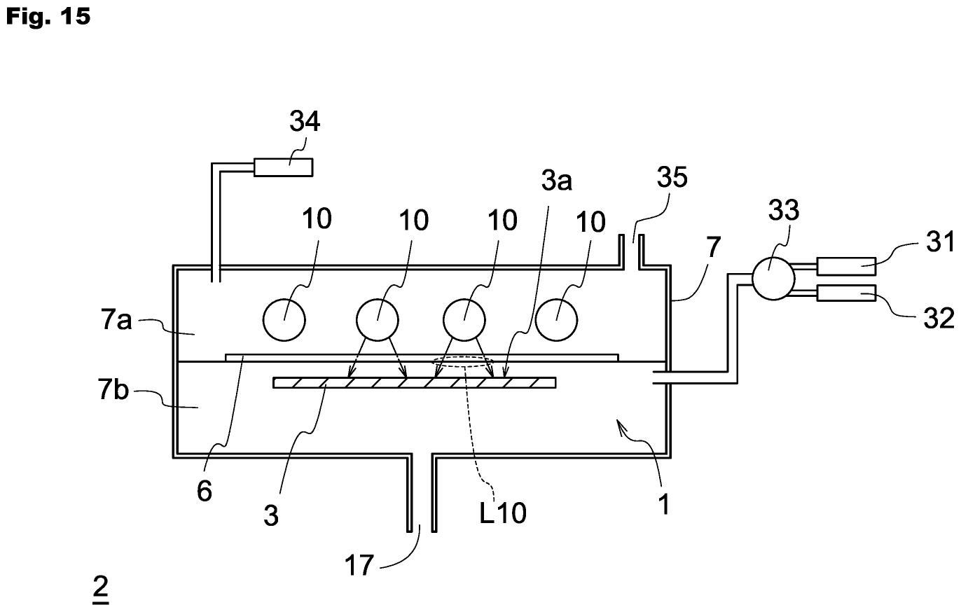

Further, as illustrated in FIG. 15, the base material 3 may be irradiated with the ultraviolet light L10 in a closed chamber 7. In the system 2 illustrated in FIG. 15, similar to system 2 illustrated in FIG. 13, a space 7a in which the Xe excimer lamp 10 is accommodated and a space 7b on which the base material 3 is placed are separated. The treatment space gas with a low oxygen concentration delivered from the gas mixer 33 is supplied to the space 7b in which the base material 3 is placed. In addition, a nitrogen gas is introduced from the nitrogen gas source 34 into the space 7a in which the Xe excimer lamp 10 is accommodated, similarly to the configuration illustrated in FIG. 13. In this case as well, it is preferable to provide a gas discharge port 17 for forcibly discharging the gas in the space 7b. The nitrogen gas source 34 may be shared with the nitrogen gas source 31.

In the base material 3 after being irradiated with the ultraviolet light L10 by the system 2 illustrated in FIGS. 13 to 15, polymer chains constituting the base material 3 are cleaved near the surface 3a, and the base material 3 is modified into a microporous layer 4a (cf. FIG. 24 to be described later) including the voids 4 (cf. FIG. 12). At this time, molecular chains with an extremely low molecular weight compared to that in the resin constituting the base material 3 may be secondarily generated at a part of a location near the surface 3a. Therefore, the base material 3 after being irradiated with the ultraviolet light L10 may be removed and subjected to an alkaline cleaning treatment, a warm water cleaning treatment, a drying treatment, or the like to remove the low-molecular-weight component. Among these, the alkaline cleaning treatment is particularly preferred.

As the alkaline cleaning treatment, a method of immersing the base material 3 after being irradiated with the ultraviolet light L10 in an alkaline solution of sodium hydroxide, potassium hydroxide, lithium hydroxide, or the like can be employed. The alkali concentration of the alkaline solution is preferably 4% to 20%, and more preferably 8% to 12%. The temperature of the alkaline solution is preferably 40° C. to 80° C., and particularly preferably 60° C. to 70° C. When the temperature of the alkaline solution is lower than 40° C., the cleaning ability is not sufficiently exhibited, and when the temperature exceeds 80° C., the alkali component is easily vaporized. The immersion time of the base material 3 in the alkaline solution is not particularly limited, but the effect of removing the low-molecular-weight material is typically expected when the immersion time is 10 seconds or more.

A more detailed description of the surface modification method according to the present invention will be described later with reference to an example. Note that this example is partially common to the description regarding the method for producing a resin plating material according to the present invention. For this reason, the embodiment of the method for producing a resin plating material will be described, and then the example will be described.

[Method for producing resin plating material, and electroless plating apparatus]Next, embodiments of the method for producing a resin plating material and an electroless plating apparatus will be described with reference to the drawings as appropriate. However, the following drawings are schematically illustrated, and the dimensional ratios in the drawings do not necessarily coincide with the actual dimensional ratios. In addition, the dimensional ratios may not coincide with each other between the drawings.

Note that, in the following drawings as well, the same elements as those in FIG. 11 are denoted by the same reference numerals, and the description thereof is simplified.

The method for producing a resin plating material according to the present invention includes: a step (a) of preparing a base material 3 containing an insulating resin material, and a step (b) of irradiating the surface of the base material 3 with ultraviolet light L10 having a wavelength of 200 nm or less in an atmosphere 1 with an oxygen concentration of 0.01 vol % to 10 vol %. This step (b) is a step of modifying a treatment target region (a region within the distance d10 in the depth direction), including a surface 3a of the base material 3, into a microporous layer 4a (cf. FIG. 24 to be described later) that includes voids 4 (cf. FIG. 12) of nm order size.

Further, the method for producing a resin plating material according to the present invention includes: a step (d) of binding a catalyst to the microporous layer 4a after the step (b); and a step (e) of forming an electroless plating layer on the upper surface of the base material through the catalyst.

The base material 3 is the same as described above. That is, the type of the base material 3 is not limited as long as the base material 3 is an insulating resin material, and examples thereof include a polyimide resin, a liquid crystal polymer, polystyrene, polyphenylene sulfide, polyether ether ketone, polyethylene naphthalate, a cycloolefin polymer, a cyclic olefin copolymer, polytetrafluoroethylene, and an epoxy-based resin. The base material 3 may be a sheet-like film or a plate-like member.

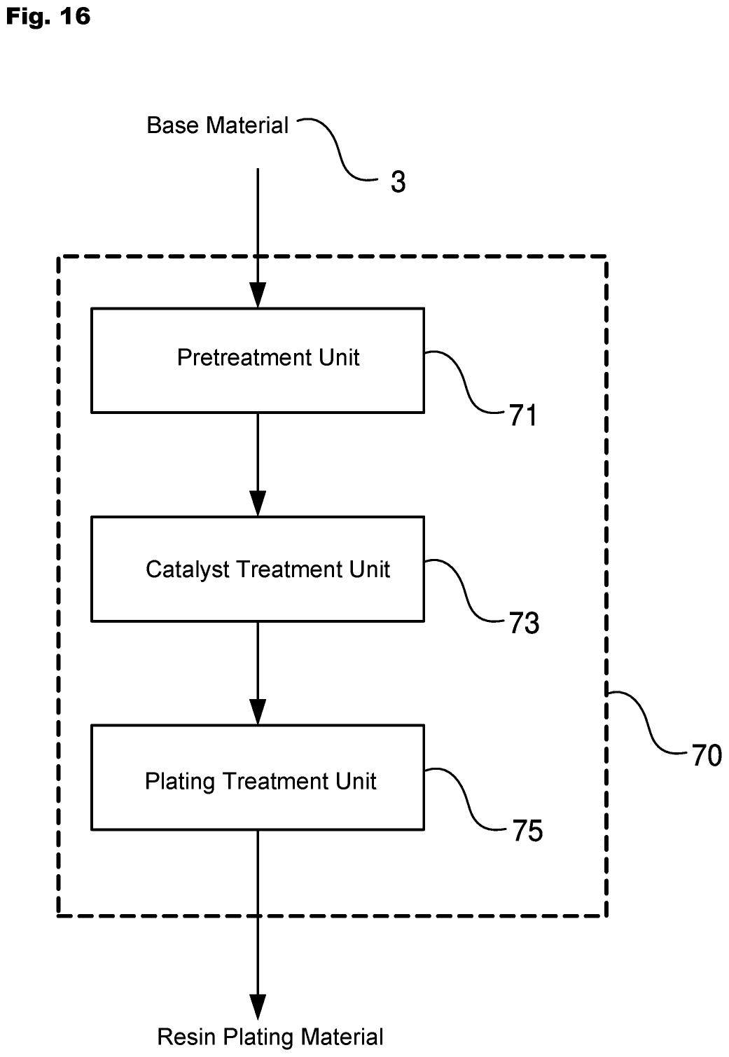

FIG. 16 is a block diagram schematically illustrating a configuration example of an electroless plating apparatus suitable for use of the method for producing a resin plating material according to the present invention. An electroless plating apparatus 70 includes a pretreatment unit 71, a catalyst treatment unit 73, and a plating treatment unit 75.

The pretreatment unit 71 is a unit that irradiates the base material 3, containing an insulating resin material, with predetermined ultraviolet light. By the base material 3 passing through the pretreatment unit 71, a microporous layer 4a, which will be described later (cf. FIG. 24 to be described later), is formed near the surface of the base material 3.

The catalyst treatment unit 73 is a unit that causes a catalyst to act on the base material 3 on which the microporous layer 4a is formed near the surface. By the base material 3 passing through the catalyst unit 73, the catalyst is bound to the microporous layer 4a.

The plating treatment unit 75 is a unit that imparts a plating material to the base material 3 to which the catalyst is bound. By the base material 3 passing through the plating unit 75, an electroless plating layer is formed on the surface of the base material 3, and a resin plating material is obtained.

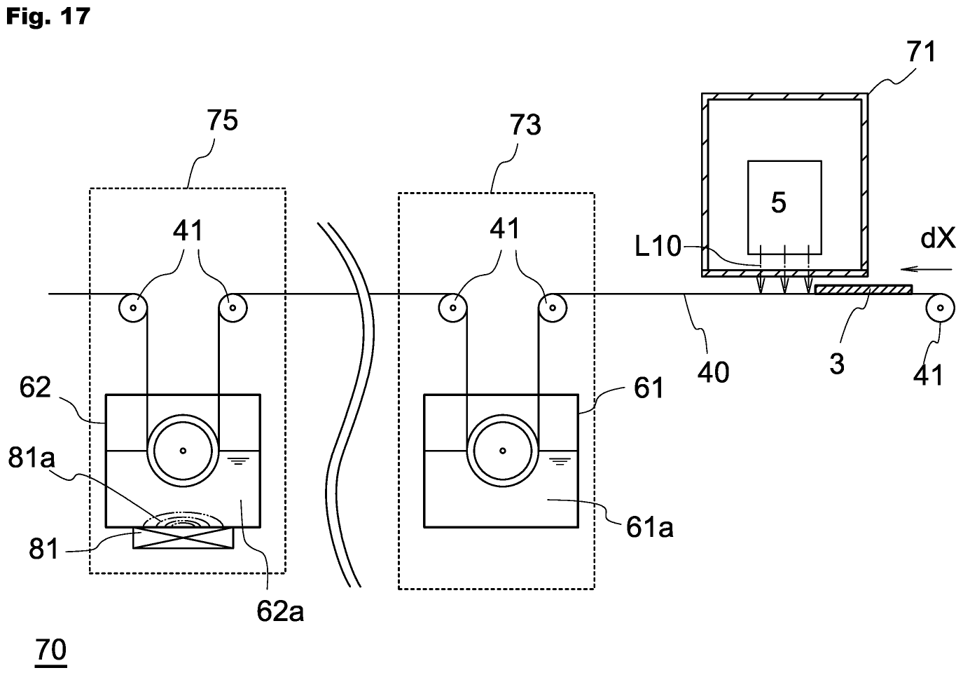

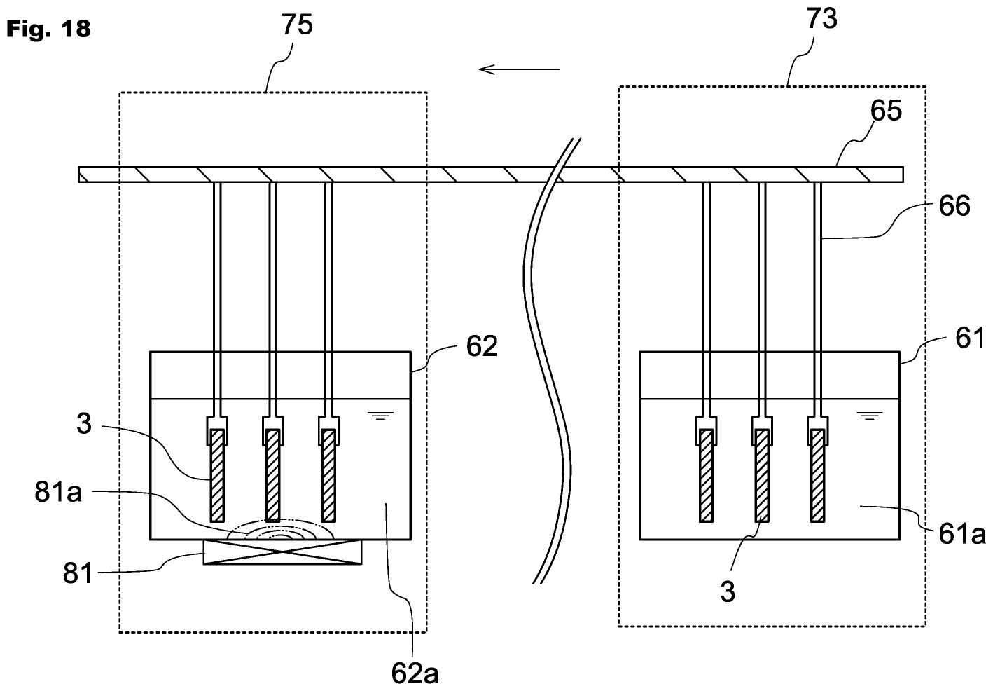

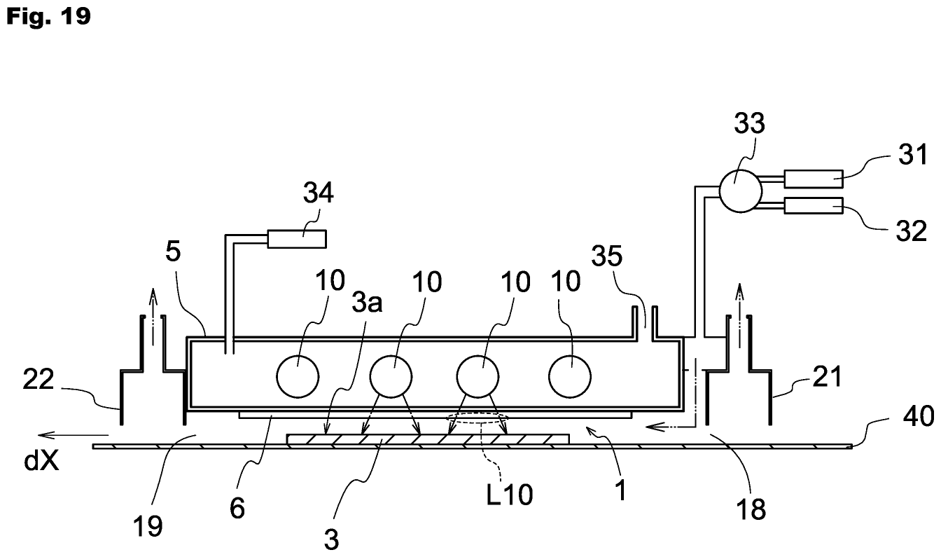

FIG. 17 is a block diagram schematically illustrating a configuration of an embodiment of the electroless plating apparatus 70. The electroless plating apparatus 70 illustrated in FIG. 17 conveys the base material 3 to be treated along a conveyance path 40 under driving of conveyance rollers 41, also forms an electroless plating layer on the surface of the base material 3. The configuration of FIG. 17 is assumed to be, for example, a case where the base material 3 has a film shape. In FIG. 17, a part of the base material 3 is exaggerated for easy understanding.

The pretreatment unit 71 includes the light source apparatus 5, and irradiates the surface of the base material 3 conveyed along the conveyance path 40 with the ultraviolet light L10. After passing through the pretreatment unit 71, the base material 3 is sent to a catalyst treatment unit 73. The catalyst treatment unit 73 includes a first storage tank 61 in which a solution (catalyst imparting solution) 61a containing a catalyst is stored. The base material 3 sent to the catalyst treatment unit 73 is immersed in the catalyst imparting solution 61a stored in the first storage tank 61.

The base material 3 after passing through the catalyst treatment unit 73 is sent to the plating treatment unit 75. The plating treatment unit 75 includes a second storage tank 62 in which a plating solution 62a is stored. The base material 3 sent to the plating treatment unit 75 is immersed in the plating solution 62a stored in the second storage tank 62.

In the present embodiment, the plating treatment unit 75 includes an ultrasonic wave generator 81 capable of generating ultrasonic waves 81a. While the base material 3 is immersed in the plating solution 62a, the ultrasonic waves 81a emitted from the ultrasonic wave generator 81 are transmitted to the base material 3 through the plating solution 62a.

Although not illustrated in FIG. 17, the electroless plating apparatus 70 may include units other than the catalyst treatment unit 73 and the plating treatment unit 75. As an example, a unit for adjusting the surface potential of the base material 3, a unit for rinsing the treated base material 3, a unit for activating the base material 3, and the like are appropriately provided as necessary.

Note that FIG. 17 illustrates a case where the pretreatment unit 71, the catalyst treatment unit 73, and the plating treatment unit 75 are configured to treat the base material 3 on a line. However, one or more of these treatment units may be configured to treat the base material 3 in a batch manner. FIG. 18 is a view schematically illustrating a configuration when the catalyst treatment unit 73 and the plating treatment unit 75 treat the base material 3 in a batch manner. When the base material 3 is a plate-like body, a batch type treatment as illustrated in FIG. 18 can be suitably used.

As illustrated in FIG. 18, a holder 66 coupled to the support member 65 may be provided, and by the movement of the holder 66, the base material 3 fixed by the holder 66 may be immersed in the catalyst imparting solution 61a in a first storage tank 61 provided in the catalyst treatment unit 73. In this case, after a predetermined time has elapsed, the holder 66 moves, whereby the base material 3 is removed from the first storage tank 61 and transferred to a subsequent treatment unit (here, the plating treatment unit 75).

Similarly, in the plating treatment unit 75, by the movement of the holder 66, the base material 3 is immersed in the plating solution 62a in a second storage tank 62 for a predetermined time, and then the base material 3 is removed from the second storage tank 62. While the base material 3 is immersed in the plating solution 62a, the ultrasonic waves 81a emitted from the ultrasonic wave generator 81 are transmitted to the base material 3 through the plating solution 62a.

FIG. 19 is a diagram schematically illustrating a configuration example of the pretreatment unit 71. The pretreatment unit 71 illustrated in FIG. 19 conveys the base material 3 to be treated along the conveyance path 40 and also performs surface treatment of the base material 3. Note that the pretreatment unit 71 illustrated in FIG. 19 is substantially common to the system 2 described above with reference to FIG. 13, and hence a detailed description thereof will be omitted.

That is, according to the pretreatment unit 71, similar to the system 2 described above, the base material 3 is irradiated with the ultraviolet light L10 while moving on the conveyance path 40 so that the region near the surface of the base material 3 is modified to the microporous layer 4a (cf. FIG. 24 to be described later) including the voids 4 (cf. FIG. 12).

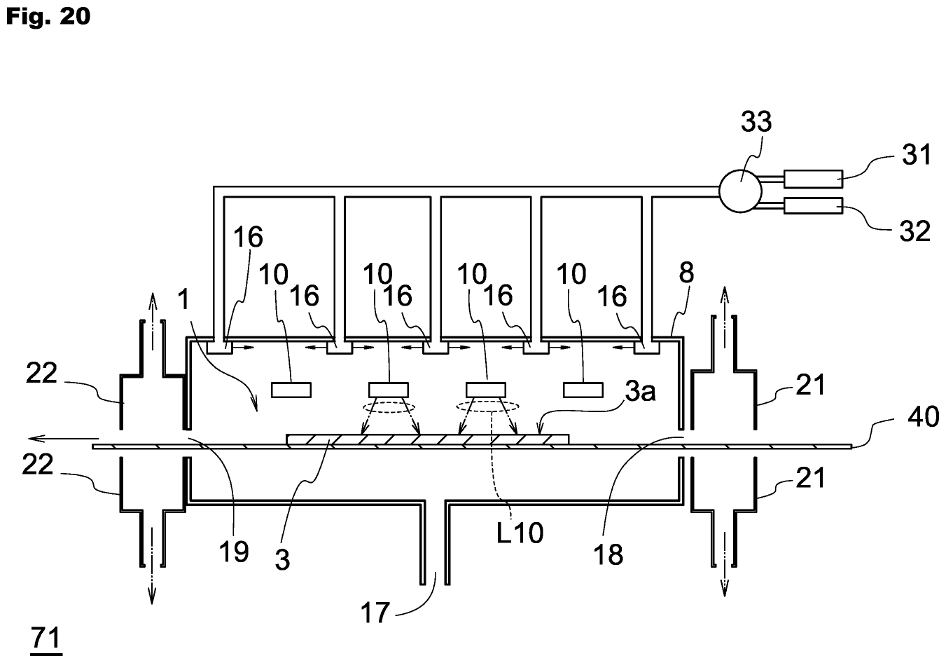

In the configuration of the pretreatment unit 71 illustrated in FIG. 19, the space (light source apparatus 5) in which the Xe excimer lamp 10 is accommodated and the space through which the base material 3 passes are separated, but as illustrated in FIG. 20, both may be disposed in the same space (treatment space 8). FIG. 20 is a view schematically illustrating another configuration example of the pretreatment unit 71 like FIG. 19.

Note that the pretreatment unit 71 illustrated in FIG. 20 is substantially common to the system 2 described above with reference to FIG. 14, and hence a detailed description thereof will be omitted.

As described above with reference to FIG. 13, in the system 2, an oxygen concentration detector (not illustrated) may be installed in the space through which the base material 3 passes, and the gas mixer 33 may be feedback-controlled so that the oxygen concentration in the atmosphere 1 in the space is at a predetermined constant value. The same applies to the pretreatment unit 71 illustrated in FIG. 19 and the pretreatment unit 71 illustrated in FIG. 20.

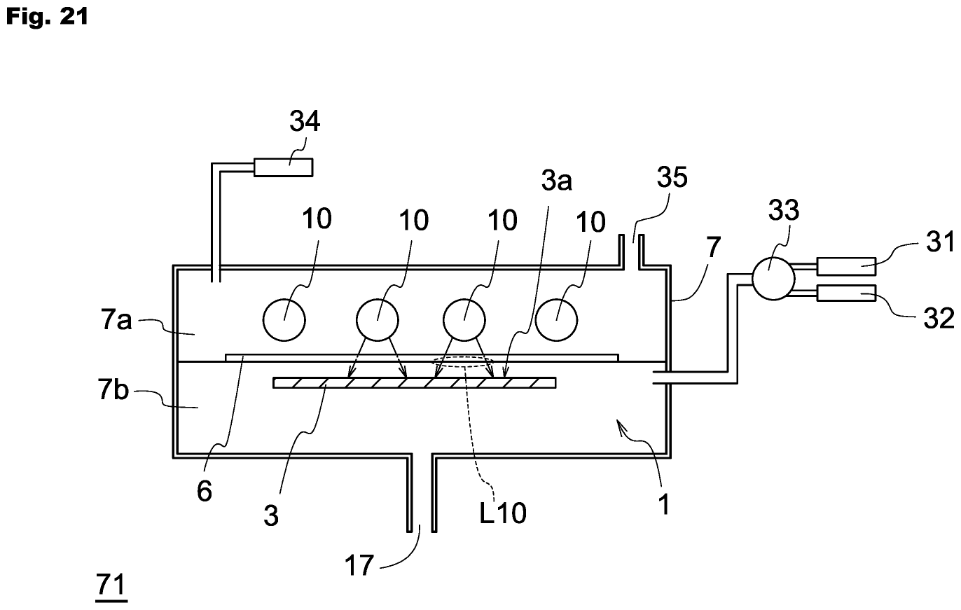

Further, as illustrated in FIG. 21, the base material 3 may be irradiated with the ultraviolet light L10 in a closed chamber 7. Since the pretreatment unit 71 illustrated in FIG. 21 is substantially common to the system 2 described above with reference to FIG. 15, a detailed description thereof will be omitted.

Similarly to the system 2 illustrated in FIGS. 13 to 15, in the base material 3 after being irradiated with the ultraviolet light L10 by the pretreatment unit 71 illustrated in FIGS. 19 to 21, polymer chains constituting the base material 3 are cleaved near the surface 3a, and the base material 3 is modified into a microporous layer 4a (cf. FIG. 24 to be described later) including the voids 4 (cf. FIG. 12). At this time, molecular chains with an extremely low molecular weight compared to that in the resin constituting the base material 3 may be secondarily generated at a part of a location near the surface 3a. Therefore, the base material 3 after being irradiated with the ultraviolet light L10 may be removed and subjected to an alkaline cleaning treatment, a warm water cleaning treatment, a drying treatment, or the like to remove the low-molecular-weight component. Among these, the alkaline cleaning treatment is particularly preferred.

The detailed method of the alkaline cleaning treatment is common to the method described above in the embodiment related to the surface modification method. Again, as the alkaline cleaning treatment, a method of immersing the base material 3 after being irradiated with the ultraviolet light L10 in an alkaline solution of sodium hydroxide, potassium hydroxide, lithium hydroxide, or the like can be employed. The alkali concentration of the alkaline solution is preferably 4% to 20%, and more preferably 8% to 12%. The temperature of the alkaline solution is preferably 40° C. to 80° C., and particularly preferably 60° C. to 70° C. When the temperature of the alkaline solution is lower than 40° C., the cleaning ability is not sufficiently exhibited, and when the temperature exceeds 80° C., the alkali component is easily vaporized. The immersion time of the base material 3 in the alkaline solution is not particularly limited, but the effect of removing the low-molecular-weight material is typically expected when the immersion time is 10 seconds or more.

That is, when the alkaline cleaning treatment is performed, an alkaline cleaning treatment unit (not illustrated) may be provided between the pretreatment unit 71 and the catalyst treatment unit 73. Similarly to the catalyst treatment unit 73, the alkaline cleaning treatment unit may be configured to include a storage tank in which a predetermined chemical solution (here, the alkaline solution described above) is stored, and to immerse the base material 3 after passing through the pretreatment unit 71 in the alkaline solution.

### Examples

Hereinafter, specific test examples are shown to describe the present invention in more detail, but the present invention is not limited to the aspects of these test examples.

(Verification 1: Oxygen concentration in atmosphere) The relationship between the irradiation time of the ultraviolet light L10 and the adhesive strength of the base material 3 was measured using a similar method to the measurement method described above with reference to FIG. 10. That is, the verification method is as follows.

As a sample of the base material 3, a polyimide resin (Kapton 100EN-C, manufactured by DU PONT-TORAY CO., LTD.) was prepared. For this sample, in a state where the oxygen concentration of the atmosphere was varied in seven patterns of 0.01 vol %, 0.1 vol %, 0.5 vol %, 1 vol %, 5 vol %, 10 vol %, and 21 vol % using a light irradiation apparatus (manufactured by USHIO INC., SVC 232 Series, peak wavelength 172 nm). the surface of the sample was irradiated with ultraviolet light L10 from a location with an irradiation distance (separation distance) of 3 mm. Note that the atmosphere with an oxygen concentration of 21 vol % corresponds to the air 100 illustrated in FIG. 6. Note that the light irradiation apparatus is equipped with the Xe excimer lamp 10.

After each sample was irradiated with the ultraviolet light L10 while varying the irradiation time, the irradiation surfaces of the same sample were pasted together with an adhesive sheet (Aron Mighty AF-700 manufactured by Toagosei Company, Limited) placed therebetween and laminated at 100° C. Thereafter, a pressure bonding process was performed at 180° C. for 30 minutes while pressing was performed at a pressure of 2 MPa to 3 MPa. The peak value of the adhesive strength of the pasted sample obtained after the pressure bonding was measured by a method according to JIS K 6854-3.

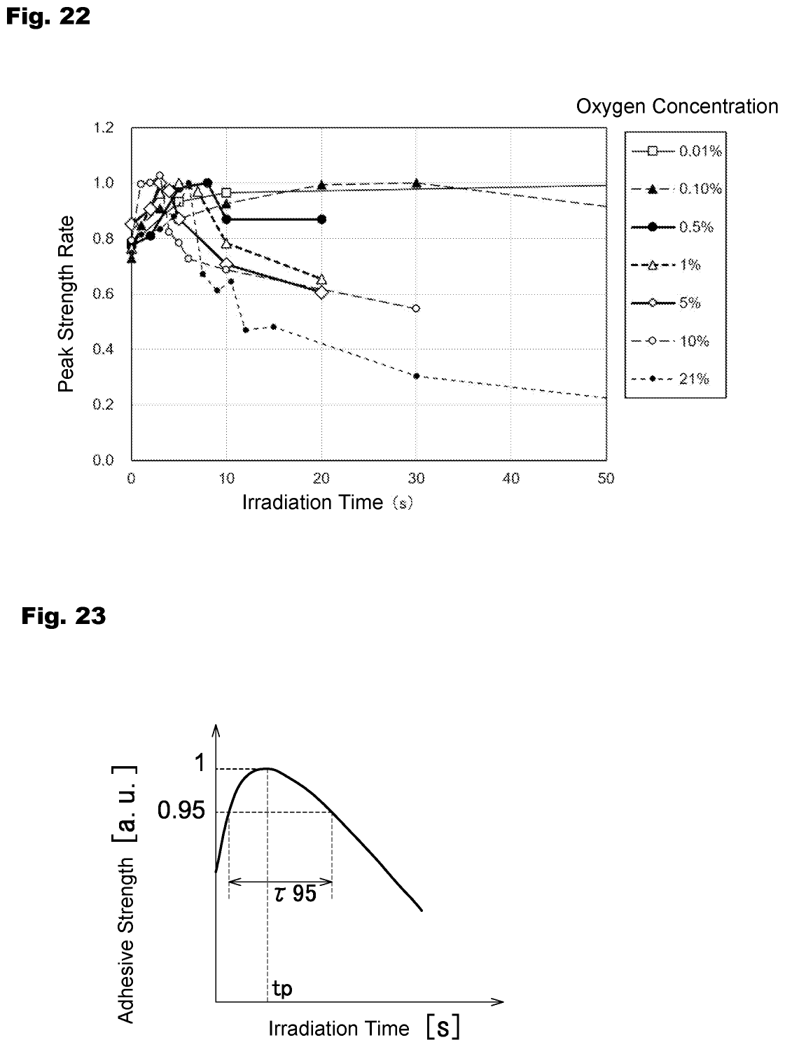

FIG. 22 is a graph with the relative value of the peak value of the adhesive strength on the vertical axis and the irradiation time of the ultraviolet light L10 on the horizontal axis.

According to FIG. 22, it can be seen that the rate of decrease in the adhesive strength due to longer irradiation time is mitigated in the case of irradiating the base material 3 with the ultraviolet light L10 in an atmosphere with a low oxygen concentration, compared to the case of irradiating the base material 3 with the ultraviolet light L 10 under an ambient atmosphere. Specifically, in the case of the ambient atmosphere, the adhesive strength reached its maximum value after about 6 seconds of irradiation time, and the adhesive strength decreased to less than 50% of the peak value as the irradiation time was further lengthened by about 6 seconds.

In contrast, in an atmosphere with an oxygen concentration of 10 vol % or less, the adhesive strength shows 50% or more of the peak value even after continuous irradiation with the ultraviolet light L10 for 20 seconds beyond the lapse of irradiation time when the adhesive strength reaches its peak value. In particular, according to the results of FIG. 22, it can be seen that the lower the oxygen concentration, the more the degree of decrease in adhesive strength due to the longer irradiation time can be suppressed.

From the results of FIG. 22, it can be seen that reducing the oxygen concentration of the atmosphere from the air (21%) increases the allowable time for irradiation with the ultraviolet light L10 to set the adhesive strength to a strength close to the peak value. In other words, the higher the ratio of the allowable time to the irradiation time required for setting the adhesive strength to the peak value, the more the flexibility is improved in the irradiation time of the ultraviolet light L10 for imparting high adhesive strength to the base material 3. That is, the higher the ratio, the more the controllability is improved during the modification treatment of the base material 3. Therefore, the level of controllability can be evaluated by the value of the ratio.

FIG. 23 is a graph for describing a “ratio” that serves as an index for evaluating the level of controllability. The allowable value of the degree of variation in discussing the adhesive strength is generally 5%. Therefore, the level of controllability can be evaluated using the ratio (r95/tp) of an allowable time T95 for irradiation with the ultraviolet light L10 to set the adhesive strength to a strength close to the peak value (i.e., 95% or more of the peak value), with an irradiation time tp required to set the adhesive strength of the base material 3 to the peak value as a reference. As another method, when the irradiation time tp required for setting the adhesive strength of the base material 3 to the peak value is 10 seconds or more, the deviation of the irradiation time is allowed to be 10 seconds or more so that it can be determined that the controllability is high.

Table 1 below illustrates the results obtained by calculating the ratio (r95/tp) using the above method in accordance with the oxygen concentration of the atmosphere based on the results of FIG. 22, and evaluating the level of controllability of the surface treatment on the base material 3 based on this value. In Table 1, a sample with a ratio (r95/tp) of 0.3 or more and high controllability is evaluated as “Evaluation A”, and a sample with low controllability is evaluated as “Evaluation C”.

TABLE 1

| | | Oxygen | | | | |
|---|---|---|---|---|---|---|
| Sample | | concentration | τ95 | tp | τ95/ | |
| number | Type | (%) | (sec) | (sec) | tp | Evaluation |
| #1 | Comparative | 21 | 1 | 6 | 0.2 | C |
| | Example 1 | | | | | |
| #2 | Example 1 | 10 | 2 | 3 | 0.7 | A |
| #3 | Example 2 | 5 | 2 | 3 | 0.7 | A |
| #4 | Example 3 | 2 | 4 | 5 | 0.8 | A |
| #5 | Example 4 | 1 | 4 | 5 | 0.8 | A |
| #6 | Example 5 | 0.5 | 5 | 8 | 0.6 | A |
| #7 | Example 6 | 0.1 | 16 | 30 | 0.5 | A |
| #8 | Example 7 | 0.01 | 180 | 120 | 1.5 | A |

According to Table 1, by making the oxygen concentration of the atmosphere lower than that of the air, the ratio (r95/tp) can be set to 0.5 or more, or the allowable time T95 can be set to 10 seconds or more. As a result, it is possible to modify only the vicinity of the surface 3a of the base material 3 without precisely controlling the irradiation time.

(Verification 2: Confirmation of microporous layer)

A catalyst is imparted to the base material 3 after being irradiated with the ultraviolet light L10, and then an electroless plating layer is formed, so that a conductive layer is formed on the surface of the insulating base material 3. FIG. 24 is a cross-sectional view schematically illustrating a state where an electroless plating layer 50 is formed on the surface of the base material 3 (i.e., “resin plating material 51”).

By irradiating the surface of the base material 3 with the ultraviolet light L10 using the method described above, the vicinity of the surface 3a of the base material 3 is modified, and the microporous layer 4a including the voids 4 (cf. FIG. 12) is formed. When the catalyst is imparted in this state, it is considered that the catalyst contributing compound is incorporated into the voids 4 in the microporous layer 4a.

Therefore, as illustrated in FIG. 24, if a substance derived from the catalyst can be detected inside the base material 3 when the cross section of the base material 3 is analyzed during traveling from the surface 3a of the base material 3 (the interface between the base material 3 and the electroless plating layer 50) toward the base material 3 side in the depth direction dZ, it is proved that the voids 4 were present near the surface 3a of the base material 3, in other words, the microporous layer 4a was formed.

The base material 3 was irradiated with the ultraviolet light L10 in the same manner as in Verification 1 under the atmosphere 1 with an oxygen concentration of 0.1%, and then the electroless plating layer 50 was formed using the following method. However, in this verification, an epoxy-based resin has been used as the base material 3.

The base material 3 after being irradiated with the ultraviolet light L10 was immediately immersed in a conditioner solution M1, and the surface potential of the base material 3 was adjusted to a cation together with a degreasing treatment. Then, after a rinsing treatment, the base material 3 was immersed in a pre-dip solution M2 to adjust the surface potential of the base material 3 to an anion. Next, the base material 3 was immersed in a catalyst imparting solution M3 to impart a catalyst complex to the surface of the base material 3. Subsequently, after the rinsing treatment, the base material 3 was immersed in an activation treatment solution M4 to reduce the catalyst complex to metal. Then, after the rinsing treatment, the base material 3 was immersed in an electroless metal plating solution M5 to reduce metal ions through the catalyst, thereby forming an electroless metal film on the surface of the base material 3.

The step of immersing the base material 3 in the catalyst imparting solution M3 corresponds to the step (d), and the step of immersing the base material 3 in the electroless metal plating solution M5 corresponds to the step (e). Note that the step of preparing the base material 3 corresponds to the step (a), and the step of irradiating the base material 3 with the ultraviolet light L1 corresponds to the step (b). That is, the resin plating material 51 is produced from the base material 3 through steps (a), (b), (d), and (e).

When the base material 3 was immersed in each chemical solution, the base material 3 was dipped in a chemical solution pod in which each chemical solution was stored for a predetermined time (several seconds to several minutes) and then removed. The rinsing treatment was performed by dipping the base material 3 into a cleaning pod in which cleaning water (pure water) was stored for a predetermined time (several seconds to several minutes) and then removing the base material 3.

Each of the chemical solutions used was as follows:
Conditioner solution M1: OPC-370 CONDICLEAN ELA (manufactured by OKUNO CHEMICAL INDUSTRIES CO., LTD.)
Pre-dip solution M2: Mixture of OPC PREDIP 49L (manufactured by OKUNO CHEMICAL INDUSTRIES CO., LTD.) and 98% sulfuric acid
Catalyst imparting solution M3: Mixture of OPC-50 INDUCER AM and OPC-50 INDUCER CM (both manufactured by OKUNO CHEMICAL INDUSTRIES CO., LTD.)
Activation treatment solution M4: Mixture of OPC-150 CLUSTER RW (manufactured by OKUNO CHEMICAL INDUSTRIES CO., LTD.) and boric acid
Electroless metal plating solution M5: Mixture of ATS ADD-COPPER IW-A, ATS ADD-COPPER IW-M, ATS ADD-COPPER IW-C, and ELECTROLESS COPPER R-N (all manufactured by OKUNO CHEMICAL INDUSTRIES CO., LTD.)

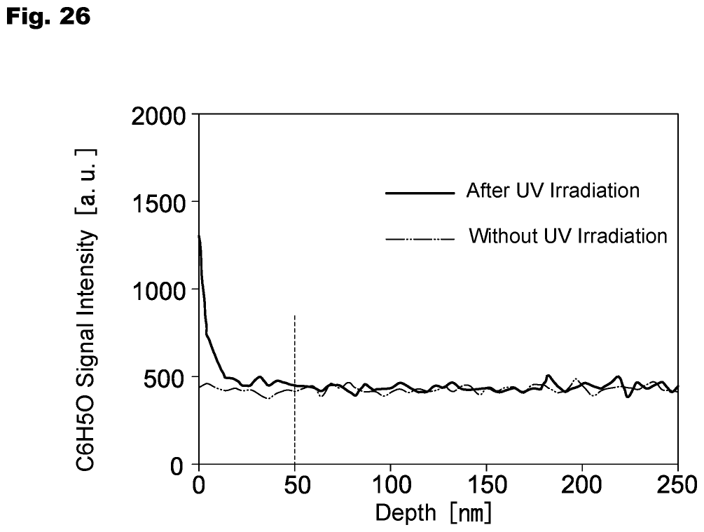

FIG. 25 is a graph illustrating the result of TEM-EDS (JEM-2100PLUS manufactured by JEOL Ltd.) analysis of the interface between the base material 3 and the electroless plating layer 50. In FIG. 25, the horizontal axis represents a travel distance (nm) from the interface between the base material 3 and the electroless plating layer 50 in the depth direction dZ. In FIG. 25, the vertical axis represents a value (cps/ROI) obtained by dividing the detection counts of palladium (Pd), which is a substance constituting the catalyst, by the effective time, where a higher value means a greater amount of Pd.

According to FIG. 25, it can be seen that Pd derived from the catalyst exists in a region proceeding from the interface between the base material 3 and the electroless plating layer 50 toward the base material 3 side by 30 nm in the depth direction dZ. From the result of FIG. 25, the thickness of the microporous layer 4a formed by forming the voids 4 in the base material 3 is estimated to be in the range of 30 nm to 40 nm.

Meanwhile, when the base material 3 is irradiated with the ultraviolet light L10, as described above, some of the polymer chains constituting the base material 3 are cleaved, and a low molecular weight substance is secondarily generated. Therefore, it is expected that mass spectrometry, performed using TOF-SIMS, on the base material 3 after being irradiated with the ultraviolet light L10, detects a substance different from the polymer material constituting the base material 3. When the ultraviolet light L10 has reached only the vicinity of the surface 3a of the base material 3, it is expected that a low molecular weight substance is detected only in this region.

A liquid crystal polymer resin defined by the following Formula (9) was prepared as the base material 3, and the base material 3 was irradiated with the ultraviolet light L10 under the atmosphere 1 with an oxygen concentration of 0.1 vol %, using a similar method to described above. Next, mass spectrometry was performed using TOF-SIMS, while sputtering was performed on the surface of the base material 3 with an Ar gas cluster ion beam (Ar-GCIB). Sputtering and mass spectrometry were both performed by TOF-SIMS 5 manufactured by ION-TOF. For comparison, the base material 3 made of the same material was subjected to mass spectrometry using the same method in a state not irradiated with the ultraviolet light L10.

In mass spectrometry, normalization was performed using the spectral intensity of C₆H₅O, which is estimated to be obtained by cleavage of some of the molecular chains of the liquid crystal polymer resin defined by Formula (9). The results are illustrated in FIG. 26.

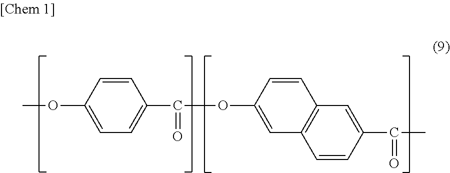

In principle, no signal derived from C₆H₅O is generated for the base material 3 that is not irradiated with the ultraviolet light L10. On the other hand, according to the results of FIG. 26, it is confirmed that the intensity of the signal derived from C₆H₅O generated from the base material 3 irradiated with the ultraviolet light L10 decreases as the light travels in the depth direction. Then, when the intensity of the signal, derived from C₆H₅O generated from the base material 3 irradiated with the ultraviolet light L10, reaches a depth position indicating the same level as the intensity of the signal, derived from C₆H₅O of the base material 3 not irradiated with the ultraviolet light L10, it is suggested that the region deeper than this is no longer substantially irradiated with the ultraviolet light L10.

That is, the results of FIG. 26 suggest that the base material 3 is modified to the microporous layer 4a over a region of about 50 nm in the depth direction from the surface 3a.

As described above, when the base material 3 is irradiated with the ultraviolet light L10, some of the polymer chains constituting the base material 3 are cleaved. Therefore, it is considered that the strength decreases near the surface of the base material 3 compared to before being irradiated with the ultraviolet light L10. Therefore, the strength in the depth direction of the base material 3 was evaluated using a micro slurry-jet erosion (MSE) test.

The MSE test is a collision abrasion test using solid fine particles and is a test in which a certain amount of fine particles are projected onto the same location on the surface of a test piece, erosion abrasion due to collision is generated, and the depth of abrasion is measured. When the depth measurement and the shape measurement are repeatedly performed to create a graph, and when layers with different hardness exist on the surface of the base material, lines on the graph have different slopes because the wear progress rate changes.

As the base material 3, a polyimide resin (Kapton 100EN-C, manufactured by DU PONT-TORAY CO., LTD.) was prepared in the same manner as that used in Verification 1. The base material 3 was irradiated with the ultraviolet light L10 under the atmosphere 1 with an oxygen concentration of 0.1 vol %, using a similar method to that described above. Next, a slurry jet containing alumina particles was locally sprayed onto the surface of the base material 3 using a spraying apparatus, and then the maximum wear depth of a local portion formed by spraying was measured using a shape measuring instrument. Then, from the ratio of the degree of wear (depth) to the amount of projected particles at the local portion sprayed, the erosion rate (=maximum wear depth μm/projected particle amount g) was calculated. As the number of projected particles, a value calculated based on the flow rate of the slurry was employed from a preset relationship for the alumina slurry containing alumina particles.

The apparatus used for the verification is as follows.
Spraying apparatus Slurry local spraying abrasion apparatus (MSE-A manufactured by Palmeso Co., Ltd.), nozzle diameter 1 mm×1 mm, projection distance 4 mm
Shape measuring instrument: Probe type shape measuring instrument (PU-EU1 manufactured by Kosaka Laboratory Ltd.), probe tip R=2 m, load 80 N, measurement magnification 20,000, measurement length 1 mm, measurement speed 0.1 mm/see

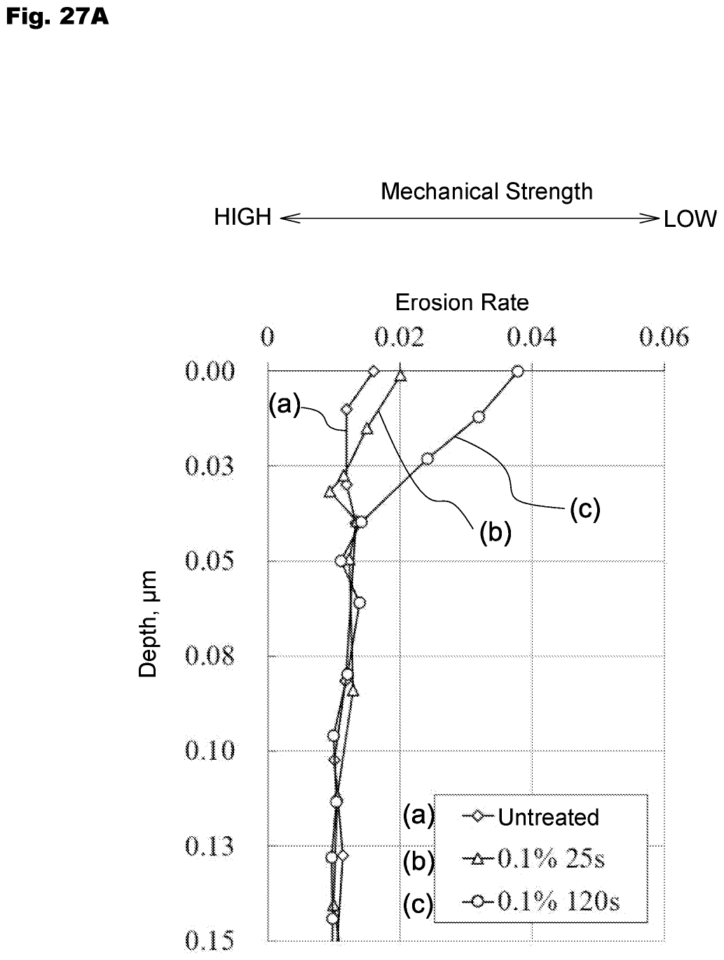

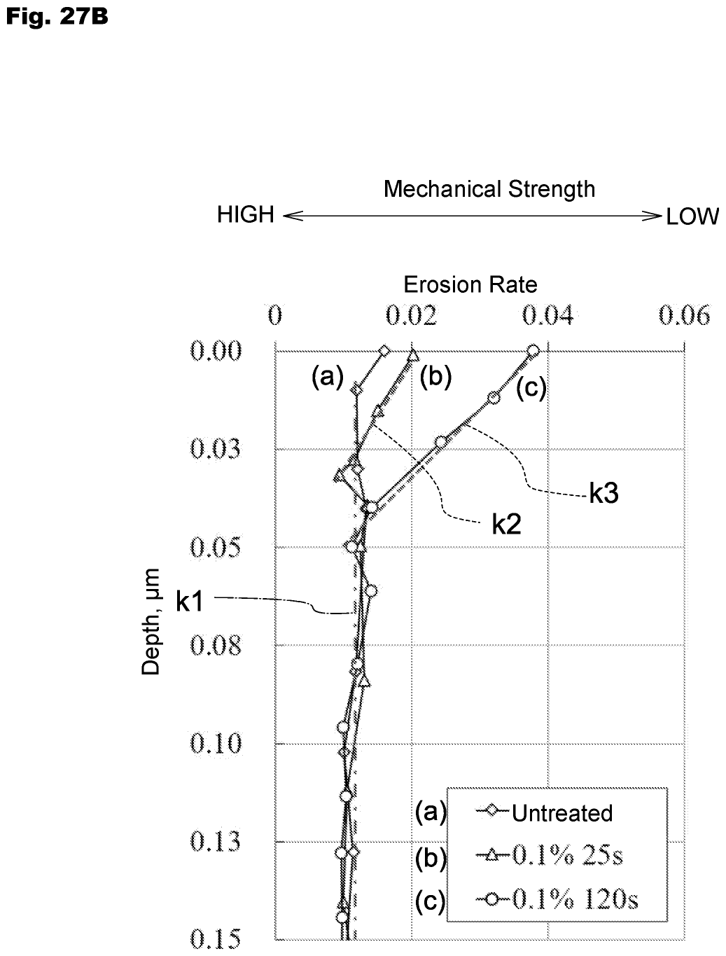

FIG. 27A is a graph in which the vertical axis represents the depth (erosion depth) and the horizontal axis represents the erosion rate. In the verification, as the base material 3, three types were used: (b) a case where the irradiation time of the ultraviolet light L10 was set to 25 seconds, (c) a case where the irradiation time was set to 120 seconds, and (a) a case where irradiation with the ultraviolet light L10 was not performed for comparison.

From the above definition, a high erosion rate means that the wear depth for the same amount of projected particles is deep, and hence the mechanical strength of the base material 3 in the region in the depth direction, to which the slurry jet was applied within that time, is low. Conversely, a low erosion rate means that the wear depth for the same amount of projected particles is shallow, and hence the mechanical strength of the base material 3 in the region in the depth direction, to which the slurry jet was applied within that time, is high. In FIG. 27A, indications of “HIGH” and “LOW” mechanical strength are schematically added for convenience of understanding.

According to FIG. 27A, it can be seen that lines (b, c) corresponding to the base material 3 irradiated with the ultraviolet light L10 are inclined at locations near the surface, and after traveling in the depth direction to a certain value, the lines indicate substantially the same slopes as a line (a) corresponding to the base material 3 not irradiated with the ultraviolet light L10. This result means that due to the irradiation with the ultraviolet light L10, the strength near the surface of the base material 3 shows a decreasing trend compared to the deep location. That is, it is suggested that the microporous layer 4a has been formed near the surface 3a of the base material 3 due to the irradiation with the ultraviolet light L10.

Even in the case where irradiation with the ultraviolet light L10 was not performed, there is a slight decrease in strength at a location very close to the surface 3a, but this is considered to have occurred in the process of producing the resin.

FIG. 27B illustrates the graph of FIG. 27A with approximate lines overlaid thereon. An approximate line k1 is an approximate line of a test result corresponding to the original strength of the base material 3 (polyimide resin) not irradiated with the ultraviolet light L10. In the graph of the results by the base material 3 irradiated with the ultraviolet light L10, approximate lines k2, k3 correspond to approximate lines of regions where the slope is greatly inflated compared to the approximate line k1.

By comparing the approximate line k1 with the approximate lines k2, k3, it is understood that the depth regions indicated by the approximate lines k2, k3 are regions where the strength of the base material 3 decreases by being irradiated with the ultraviolet light L10, that is, a region where the microporous layer 4a is formed. Therefore, in the base material 3 irradiated with the ultraviolet light L10 for 25 seconds, it is concluded that the microporous layer 4a is formed up to the depth region at the position of the intersection of the approximate line k1 and the approximate line k2. Similarly, in the base material 3 irradiated with the ultraviolet light L10 for 120 seconds, it is concluded that the microporous layer 4a is formed up to the depth region at the position of the intersection of the approximate line k1 and the approximate line k3.

According to the results of FIG. 27B, when a polyimide resin is used as the base material 3 and the base material 3 is irradiated with ultraviolet light L10 for 25 seconds, it can be estimated that the microporous layer 4a is modified over a region of about 30 nm in the depth direction from the surface 3a of the base material 3. Similarly, when a polyimide resin is used as the base material 3 and the base material 3 is irradiated with ultraviolet light L10 for 120 seconds, it can be estimated that the microporous layer 4a is modified over a region of about 50 nm in the depth direction from the surface 3a of the base material 3.

(Verification 3: Cleaning with alkaline solution) The effect obtained by subjecting the base material 3 to treatment with the ultraviolet light L10 and then to alkaline cleaning was verified. As a sample of the base material 3, the same material as in Verification 1 was used.

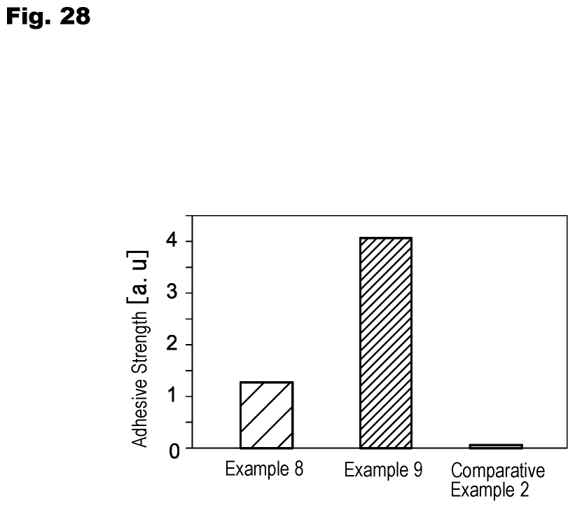

The surface of the sample was irradiated with the ultraviolet light L10 from a location with an irradiation distance of 3 mm under an atmosphere with an oxygen concentration of 0.2 vol % using an ultraviolet irradiation apparatus (manufactured by USHIO INC., SVC 232 Series, peak wavelength 172 nm). Thereafter, a comparison of the adhesive strength was performed using: the peak value of the adhesive strength, measured in the same manner as in Verification 1 without performing the alkaline cleaning treatment, as Example 8; and the peak value of the adhesive strength, measured in the same manner as in Verification 1 after the performance of the alkaline cleaning treatment, as Example 9. The results are illustrated in FIG. 28. In FIG. 28, for comparison, the peak value of the adhesive strength of the sample not subjected to the irradiation treatment with the ultraviolet light L10 is shown as Comparative Example 2.

In Example 9, specifically, the alkaline cleaning treatment was performed using the following method.

The sample (base material 3) after being irradiated with the ultraviolet light L 10 was immersed in a 2.5 mol/L (10 mass % concentration) NaOH aqueous solution heated to 65° C. for 2 minutes. Thereafter, the sample was removed and then immersed in pure water for 1 minute to be cleaned.

As can be seen from FIG. 28, the adhesive strength of the base material 3 is further increased by subjecting the base material 3 to treatment with the ultraviolet light L10 and then to alkaline cleaning. In the case of the sample of Example 8 not subjected to alkaline cleaning, molecules of the adhesive contained in the adhesive sheet are bound to the low molecular chains secondarily generated by irradiation with the ultraviolet light L10. The molecules of the adhesive do not contribute to bonding associated with pasting. That is, it is presumed that since a part of the introduced adhesive does not contribute to bonding between the base material 3 and another layer, the adhesive strength has decreased more than that in Example 9.

In the case of Example 9, the base material 3 is subjected to treatment with the ultraviolet light L10 and then to alkaline cleaning, so that pasting is performed to the surface of the base material 3, from which the low molecular chains have been removed, through the adhesive sheet. As a result, most of the introduced adhesive can be incorporated into the voids 4 (cf. FIG. 12) in the microporous layer 4a (cf. FIG. 24) generated by the treatment with the ultraviolet light L10. Thereby, it is considered that the adhesive strength was further increased compared to Example 8.

From such a viewpoint, it is considered that the effect of further increasing the adhesive strength can be similarly obtained by removing the low-molecular-weight material, using a method other than alkaline cleaning, after the treatment with ultraviolet light.

In this Verification 3, the adhesive strength was verified using an adhesive, but from the viewpoint of binding a material for achieving bonding in the voids 4 in the microporous layer 4a, the same discussion as in the case of bonding by a catalyst is possible. That is, even in the case of forming the electroless plating layer, it is estimated that the effect of further increasing the adhesive strength can be obtained by performing the alkaline cleaning treatment in advance.

(Verification 4: Plating treatment with ultrasonic vibration)

The effect of imparting the ultrasonic waves 81a during the plating treatment in the plating treatment unit 75 was verified.

Example 10: The base material 3 was irradiated with the ultraviolet light L10 under the atmosphere 1 with an oxygen concentration of 0.1%, and then the electroless plating layer 50 was formed using a method in accordance with Verification 2. However, as the base material 3, the same polyimide-based resin (Kapton 100EN-C, manufactured by DU PONT-TORAY CO., LTD.) as in Verification 1 was used. Therefore, the chemical solution used at the time of plating treatment was as follows, unlike Verification 2.
Conditioner solution M1: TOP SAPINA PRECONDITIONER (manufactured by OKUNO CHEMICAL INDUSTRIES CO., LTD.)
Pre-dip solution M2: Mixture of TOP SAPINA PREDIP (manufactured by OKUNO CHEMICAL INDUSTRIES CO., LTD.) and 98% sulfuric acid
Catalyst imparting solution M3: Mixture of TOP SAPINA CATALYST A and TOP SAPINA CATALYST C (both manufactured by OKUNO CHEMICAL INDUSTRIES CO., LTD.)
Activation treatment solution M4: Mixture of TOP SAPINA ACCELERATOR (manufactured by OKUNO CHEMICAL INDUSTRIES CO., LTD.) and boric acid
Electroless metal plating solution M5: Mixture of TOP SAPINA COPPER A, TOP SAPINA COPPER B, TOP SAPINA COPPER C, TOP SAPINA COPPER D (all manufactured by OKUNO CHEMICAL INDUSTRIES CO., LTD.), and 25% aqueous ammonia solution

However, in this verification 4, when the base material 3 was immersed in the electroless metal plating solution M5, the ultrasonic wave generator 81 was driven to transmit the ultrasonic waves 81a to the electroless metal plating solution M5. As the ultrasonic wave generator 81, MCS-2 manufactured by AS ONE Corporation was used, and ultrasonic waves 81a were input at a frequency of 40 kHz over 5 minutes.

Example 11: The base material 3 was subjected to plating treatment in the same manner as in Example 10 except that the ultrasonic wave generator 81 was not driven.

Comparative Example 3 The base material 3 was subjected to plating treatment in the same manner as in Example 10 except that irradiation with the ultraviolet light L10 as pretreatment was not performed.

Comparative Example 4 The base material 3 was subjected to plating treatment in the same manner as in Comparative Example 3 except that the ultrasonic wave generator 81 was not driven.

The surface of a resin plating material obtained using each of the base materials of Example 10, Example 11, Comparative Example 3, and Comparative Example 4 was observed with a microscope while being illuminated. The results are shown in Table 2.

TABLE 2

| | | Ultrasonic | | |
|---|---|---|---|---|
| | UV | wave | | Comprehensive |
| Type | irradiation | impartation | Pinholes | evaluation |
| Comparative | Not | Not | Present | C |
| Example 3 | performed | performed | | |
| Comparative | Not | Performed | — | C |
| Example 4 | performed | | (Plating | |
| | | | defect) | |
| Example 10 | Performed | Performed | Absent | A |
| Example 11 | Performed | Not | Present | B |
| | | performed | | |

In the resin plating material of Comparative Example 3, a plurality of pinholes were confirmed on the plating surface. In addition, in the resin plating material of Comparative Example 4, plating had been peeled off from the surface, and a plating defect was confirmed.

In the resin plating material of Example 10, no pinhole was confirmed. In the resin plating material of Example 11, pinholes were confirmed in the same manner as in Comparative Example 3. However, as described below, the resin plating material of Example 11 has a stronger adhesive force of plating compared to that of Comparative Example 3 and is more excellent in performance as a resin plating material than that of Comparative Example 3.

An electrolytic copper plating layer was formed on each of the resin plating materials of Example 11 and Comparative Example 3 using a known method, and then the peel strength was measured in accordance with Test Method A specified in JIS C 6471: 1995 (Test method for copper-clad laminates for flexible printed wiring boards). As a result, the resin plating material of Example 11 had a peel strength of 9.5 N/cm, whereas the resin plating material of Comparative Example 3 had a peel strength of 8.0 N/cm.

When the ultrasonic waves 81a are transmitted to the electroless metal plating solution M5 using the ultrasonic wave generator 81, the frequency of the ultrasonic waves 81a is preferably 10 kHz to 200 kHz and more preferably 20 kHz to 100 kHz. When the ultrasonic waves 81a with a high frequency exceeding 200 kHz is transmitted to the electroless metal plating solution M5, catalyst particles adsorbed on the resin plating material and aggregates thereof are removed, and the electroless plating layer 50 (cf. FIG. 24) may not be formed. On the other hand, when the frequency of the ultrasonic waves 81a is as low as below 10 kHz, the energy of vibration may not be sufficient to remove bubbles adhering to the surface of the base material of the base material 3.

In the above embodiment, the case where the ultrasonic waves 81a are imparted during the execution of the step (e) of forming the electroless plating layer has been described. However, a case where the ultrasonic waves 81a are not imparted is also within the scope of the present invention.

### DESCRIPTION OF REFERENCE SIGNS

1 Atmosphere
2 System
3 Base material
3a Surface of base material
4 Void
4a Microporous layer
5 Light source apparatus
6 Irradiation window
7 Chamber
7a Space in chamber
7b Space in chamber
8 Treatment space
10 Xe excimer lamp
16 Gas supply pipe
17 Gas outlet
18 Loading port
19 Unloading port
21 Sub-chamber
22 Sub-chamber
31 Nitrogen gas source
32 Oxygen-containing gas source
33 Gas mixer
34 Nitrogen gas source
35 Exhaust port
40 Conveyance path
50 Electroless plating layer
51 Resin plating material
61 First storage tank
61a Catalyst imparting solution
62 Second storage tank
62a Plating solution
65 Support member
66 Holder
70 Electroless plating apparatus
71 Pretreatment unit
73 Catalyst treatment unit
75 Plating treatment unit
81 Ultrasonic wave generator
81a Ultrasonic wave
90 Low-pressure mercury lamp
100 Air
L10 Ultraviolet light
L90 Ultraviolet light

1. A surface modification method comprising:
a step (a) of preparing a base material containing an insulating resin material; and
a step (b) of irradiating a surface of the base material with ultraviolet light having a wavelength of 200 nm or less, in an atmosphere with an oxygen concentration of 0.01 vol % to 10 vol %, to modify a treatment target region including the surface of the base material, into a microporous layer including a void of nanometer (nm) order size.

2. The surface modification method according to claim 1, wherein the treatment target region is a region between the surface and a location proceeding 3 nm to 50 nm from the surface in a depth direction orthogonal to the surface.

3. The surface modification method according to claim 1, further comprising a step (c) of removing a low-molecular-weight component contained in the base material after the step (b).

4. The surface modification method according to claim 3, wherein the step (c) is a step of immersing the base material in an alkaline solution after execution of the step (b).

5. The surface modification method according to claim 1, wherein
the step (a) includes a step of placing the base material on a conveyance path,
the step (b) includes a step of irradiating the base material with the ultraviolet light from an ultraviolet light source in a treatment space where the ultraviolet light source is accommodated, while conveying the base material,
a nitrogen gas is introduced into the treatment space during execution of the step (b), and
the step (b) ends at latest at a point when the base material passes through the treatment space.

6. The surface modification method according to claim 1-er 2, wherein
the step (a) includes a step of placing the base material at a predetermined location in a chamber, and
the step (b) includes a step of closing a space that includes the predetermined location in the chamber in a state where the space is set to an atmosphere including a mixed gas that contains oxygen with a concentration of 0.01 vol % to 10 vol % and nitrogen, and then irradiating the base material with the ultraviolet light from an ultraviolet light source installed in the chamber.

7. A method for producing a resin plating material including the surface modification method according to claim 1, the method comprising:
a step (d) of binding a catalyst to the microporous layer after the step (a) and the step (b); and
a step (e) of forming an electroless plating layer on an upper surface of the base material through the catalyst after the step (d).

8. The method for producing a resin plating material according to claim 7, wherein vibration by ultrasonic waves is imparted during execution of the step (e).

9. The method for producing a resin plating material according to claim 7, wherein the treatment target region is a region between the surface and a location proceeding 3 nm to 50 nm from the surface in a depth direction orthogonal to the surface.

10. The method for producing a resin plating material according to claim 7, the method further comprising a step (c) of removing a low-molecular-weight component contained in the base material after the step (b) and before the step (d).

11. The method for producing a resin plating material according to claim 10,
wherein the step (c) is a step of immersing the base material in an alkaline solution after execution of the step (b).

12. An electroless plating apparatus, comprising:
a pretreatment unit that irradiates a base material containing an insulating resin material with ultraviolet light having a wavelength of 200 nm or less;
a catalyst treatment unit that includes a first storage tank storing a solution containing a catalyst, and in which the base material, after being irradiated with the ultraviolet light by the pretreatment unit, is positioned in the first storage tank; and
a plating treatment unit that includes a second storage tank storing a plating solution, and in which the base material, after being removed from the catalyst treatment unit, is positioned in the second storage tank,
wherein the pretreatment unit includes a nitrogen gas source, and irradiates the base material, positioned in an irradiation region irradiated with the ultraviolet light from the nitrogen gas source, with the ultraviolet light in a state where an oxygen concentration of an atmosphere in the irradiation region is adjusted to 0.01 vol % to 10 vol % by introducing nitrogen into the irradiation region.

13. The electroless plating apparatus according to claim 12, wherein the plating treatment unit includes an ultrasonic wave generator capable of transmitting ultrasonic waves to the plating solution in the second storage tank, and the base material, after being removed from the catalyst treatment unit, is positioned in the second storage tank in a state where the ultrasonic wave, generated by the ultrasonic wave generator, is transmitted to the plating solution.

14. The electroless plating apparatus according to claim 12, further comprising a conveyance path that connects the pretreatment unit, the catalyst treatment unit, and the plating treatment unit,
wherein respective treatments in the pretreatment unit, the catalyst treatment unit, and the plating treatment unit are executed while the base material moves on the conveyance path.

15. The surface modification method according to claim 2, further comprising a step (c) of removing a low-molecular-weight component contained in the base material after the step (b).

16. The surface modification method according to claim 15, wherein the step (c) is a step of immersing the base material in an alkaline solution after execution of the step (b).

17. The surface modification method according to claim 2, wherein
the step (a) includes a step of placing the base material on a conveyance path,
the step (b) includes a step of irradiating the base material with the ultraviolet light from an ultraviolet light source in a treatment space where the ultraviolet light source is accommodated, while conveying the base material,
a nitrogen gas is introduced into the treatment space during execution of the step (b), and
the step (b) ends at latest at a point when the base material passes through the treatment space.

18. The surface modification method according to claim 2, wherein
the step (a) includes a step of placing the base material at a predetermined location in a chamber, and
the step (b) includes a step of closing a space that includes the predetermined location in the chamber in a state where the space is set to an atmosphere including a mixed gas that contains oxygen with a concentration of 0.01 vol % to 10 vol % and nitrogen, and then irradiating the base material with the ultraviolet light from an ultraviolet light source installed in the chamber.

19. The method for producing a resin plating material according to claim 8, wherein the treatment target region is a region between the surface and a location proceeding 3 nm to 50 nm from the surface in a depth direction orthogonal to the surface.

20. The method for producing a resin plating material according to claim 8, the method further comprising a step (c) of removing a low-molecular-weight component contained in the base material after the step (b) and before the step (d).
